(19) United States
(12) Patent Application Publication
(10) Pub. No.: US 2025/0290191 A1
(43) Pub. Date: Sep. 18, 2025

(54) MEMBER AND METHOD FOR PRODUCING SAME

(71) Applicants: AGC Inc., Tokyo (JP); TSUBASA SCIENCE CORPORATION, Yokohama-shi (JP)

(72) Inventors: Shuhei OGAWA, Tokyo (JP); Tomonori OGAWA, Tokyo (JP); Koji KAWAHARA, Tokyo (JP); Rui MATSUMURA, Tokyo (JP); Michio ISHIKAWA, Yokohama-shi (JP); Michio TANIMURA, Yokohama-shi (JP); Hidekazu OKADA, Yokohama-shi (JP)

(73) Assignees: AGC Inc., Tokyo (JP); TSUBASA SCIENCE CORPORATION, Yokohama-shi (JP)

(21) Appl. No.: 19/201,482

(22) Filed: May 7, 2025

Related U.S. Application Data
(63) Continuation of application No. PCT/JP2023/037760, filed on Oct. 18, 2023.

(30) Foreign Application Priority Data
Nov. 11, 2022 (JP) 2022-181022
Mar. 29, 2023 (JP) 2023-053613

(51) Int. Cl. C23C 14/28; C23C 14/08

(52) U.S. Cl. CPC C23C 14/28; C23C 14/083

(57) ABSTRACT

The present invention relates to a member including: a substrate; at least one stress-relaxation layer; and an yttrium-based protective film, in this order, in which the yttrium-based protective film has a Vickers hardness of 800 HV or more. The present invention relates to the member in which the yttrium-based protective film has a heat resistance temperature of 300° C. or higher.

### CROSS-REFERENCE TO RELATED APPLICATIONS

This is a continuation of International Application No. PCT/JP2023/037760 filed on Oct. 18, 2023, and claims priority from Japanese Patent Applications No. 2022-181022 filed on Nov. 11, 2022, and No. 2023-053613 filed on Mar. 29, 2023, the entire contents of which are incorporated herein by reference.

### TECHNICAL FIELD

The present invention relates to a member and a method for producing the same.

### BACKGROUND ART

When a semiconductor device is produced, for example, a surface of a semiconductor substrate (silicon wafer) is microfabricated by dry etching using halogen-based gas plasmas in a chamber, and the chamber from which the semiconductor substrate is taken out after the dry etching is cleaned using oxygen gas plasmas.

At this time, a member exposed to the plasma in the chamber is corroded, and a corroded part may fall off in the form of particles from the corroded member. The fallen particles adhere to the semiconductor substrate and may become a foreign substance that causes a defect in a circuit.

In the related art, a protective film (yttrium-based protective film) containing yttrium oxides or yttrium oxyfluorides has been known as a protective film for protecting the member exposed to plasmas.

Patent Literature 1 discloses a thermal sprayed coating that is formed by thermal spraying and contains yttrium oxides or yttrium oxyfluorides.

### CITATION LIST

### Patent Literature

Patent Literature 1: JP2018-76546A

### SUMMARY OF INVENTION

### Technical Problem

The present inventors have studied and found that the yttrium-based protective film in the related art may have insufficient heat resistance and insufficient plasma resistance (corrosion resistance against plasmas).

The present invention has been made in view of the above points, and an object thereof is to provide a member including an yttrium-based protective film having excellent heat resistance and excellent plasma resistance.

### Solution to Problem

As a result of intensive studies, the inventors of the present invention have found that the above object can be achieved by adopting the following configuration, and have completed the present invention.

That is, the present invention provides the following [1] to [25].

[1]A member including a substrate, at least one stress-relaxation layer, and an yttrium-based protective film, in this order, in which the yttrium-based protective film has a Vickers hardness of 800 HV or more.

[2] The member according to the above [1], in which the yttrium-based protective film has a heat resistance temperature of 300° C. or higher.

[3] The member according to the above [1] or [2], in which the stress-relaxation layer has a thickness of 0.05 μm to 9.0 μm.

[4] The member according to any one of the above [1] to [3], in which the substrate has a surface roughness on a film formation surface of 0.001 μm or more and less than 4.5 μm in terms of an arithmetic average roughness Ra.

[5] The member according to any one of the above [1] to [4], in which the stress-relaxation layer includes at least one oxide selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

[6] The member according to the above [5], in which the stress-relaxation layer includes at least two oxides selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

[7] The member according to the above [5], in which the stress-relaxation layer includes at least one oxide selected from the group consisting of Al₂O₃, SiO₂, and Y₂O₃, the stress-relaxation layer has a content of Al₂O₃ of 0 mol % to 70 mol %, the stress-relaxation layer has a content of SiO₂ of 0 mol % to 90 mol %, the stress-relaxation layer has a content of Y₂O₃ of 0 mol % to 60 mol %, and the stress-relaxation layer has a content of the oxide excluding Al₂O₃, SiO₂, and Y₂O₃ of 20 mol % or less.

[8] The member according to the above [5], in which the stress-relaxation layer includes SiO₂ and Y₂O₃, the stress-relaxation layer has SiO₂/Y₂O₃, which is a molar ratio of SiO₂ to Y₂O₃, of 90/10 to 20/80, and the stress-relaxation layer has a content of the oxide excluding SiO₂ and Y₂O₃ of 10 mol % or less.

[9] The member according to the above [5], in which the stress-relaxation layer includes Al₂O₃, and the stress-relaxation layer has a content of Al₂O₃ of 10 mol % to 70 mol %.

[10] The member according to any one of the above [1] to [9], further including at least one base layer between the substrate and the stress-relaxation layer, in which the base layer includes at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

[11] The member according to the above [10], including two or more of the base layers, in which the oxides in the adjacent base layers are different from each other.

[12] The member according to the above [10] or [11], in which the base layer includes SiO₂, or includes at least two oxides selected from the group consisting of Al₂O₃, SiO₂, and Y₂O₃.

[13] The member according to any one of the above [1] to [12], in which the yttrium-based protective film has a porosity of less than 2.0 volume %.

[14] The member according to any one of the above [1] to [13], in which the yttrium-based protective film has a thickness of 0.3 μm or more and 15 μm or less.

[15] The member according to any one of [1] to [14], in which the yttrium-based protective film has a crystallite size of 6 nm or more and 40 nm or less.

[16] The member according to any one of the above [1] to [15], in which the yttrium-based protective film includes an yttrium oxide.

[17] The member according to the above [16], in which a degree of orientation of a (222) plane of Y₂O₃ in the yttrium-based protective film is 50% or more.

[18] The member according to any one of the above [1] to [15], in which the yttrium-based protective film has a peak intensity ratio of Y₅O₄F₇ in an X-ray diffraction pattern of 60% or more.

[19] The member according to any one of the above [1] to [18], in which the substrate is formed of at least one selected from the group consisting of carbon, ceramic, and metal.

[20] The member according to [19], in which the ceramic is aluminum oxide or quartz.

[21] The member according to any one of the above [1] to [20], in which a maximum length of a film formation surface of the substrate is 30 mm or more, the substrate includes, as the film formation surface, a first film formation surface defining the maximum length and a second film formation surface different from the first film formation surface, an angle formed by the first film formation surface and the second film formation surface is 200 to 120°, and a proportion of an area of the second film formation surface to a total area of the film formation surfaces is 60% or less.

[22] The member according to any one of the above [1] to [21], which is used in a plasma etching apparatus or a plasma CVD apparatus.

[23]A method for producing the member according to any one of the above [1] to [22], the method including: forming the yttrium-based protective film by causing an evaporation source to evaporate and adhere to a surface of the stress-relaxation layer while emitting ions of at least one element selected from the group consisting of oxygen, argon, neon, krypton, and xenon in a vacuum, in which Y₂O₃ is used, or Y₂O₃ and YF₃ are used as the evaporation source.

[24] The method for producing the member according to the above [23], in which the substrate has a temperature of 320° C. or higher during the formation of the yttrium-based protective film.

[25] The method for producing the member according to the above [23] or [24], in which the at least one stress-relaxation layer is formed on a surface of the substrate before forming the yttrium-based protective film.

### Advantageous Effects of Invention

According to the present invention, a member with an yttrium-based protective film having excellent heat resistance and excellent plasma resistance can be provided.

### BRIEF DESCRIPTION OF DRAWINGS

FIG. 1 is a schematic diagram illustrating an example of a member.

FIG. 2 is a schematic diagram illustrating a ring-shaped substrate with a half cut away.

FIG. 3 is a schematic diagram illustrating a part of a cross section of another ring-shaped substrate.

FIG. 4 is a schematic diagram illustrating a part of a cross section of still another ring-shaped substrate.

FIG. 5 is a schematic diagram illustrating an apparatus used for producing an yttrium-based protective film.

### DESCRIPTION OF EMBODIMENTS

The terms used in the present invention have the following meanings.

A numerical range represented using “to” means a range including numerical values described before and after “to” as a lower limit value and an upper limit value.

### [Member]

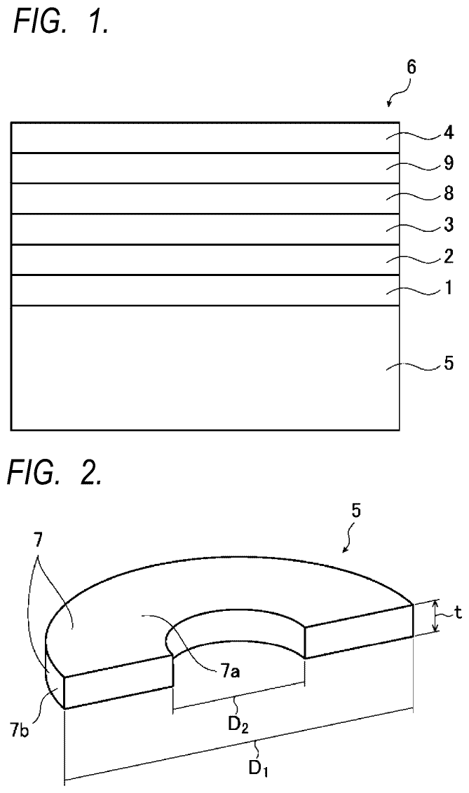

FIG. 1 is a schematic diagram illustrating an example of a member 6.

The member 6 includes at least a substrate 5, a stress-relaxation layer (a stress-relaxation layer 8 and a stress-relaxation layer 9), and an yttrium-based protective film 4 in this order. However, the stress-relaxation layer is not limited to two layers.

As shown in FIG. 1, a base layer (a base layer 1, a base layer 2, and a base layer 3) may be disposed between the substrate 5 and the stress-relaxation layer (the stress-relaxation layer 8). However, the number of the base layers is not limited to three.

The member according to the present embodiment (hereinafter, also referred to as “the present member”) includes the present protective film described below, as the yttrium-based protective film.

The surface of the present member is covered with the present protective film, and therefore, the present member has excellent plasma resistance like the present protective film.

Hereinafter, each part of the present member will be described in detail.

### <Yttrium-Based Protective Film>

Hereinafter, the yttrium-based protective film is also simply referred to as a “protective film”, and the yttrium-based protective film (protective film) included in the member (the present member) according to the present embodiment is also referred to as “the present protective film”.

The present protective film has excellent heat resistance and excellent plasma resistance.

Hereinafter, the present protective film will be described in more detail.

### Vickers Hardness

For the reason that the present protective film has excellent heat resistance and excellent plasma resistance, the Vickers hardness of the present protective film is 800 HV or more, preferably 1000 HV or more, more preferably 1100 HV or more, still more preferably 1200 HV or more, yet still more preferably 1250 HV or more, particularly preferably 1300 HV or more, even still more preferably 1350 HV or more, and most preferably 1400 HV or more.

On the other hand, the Vickers hardness of the present protective film is preferably 1800 HV or less, and more preferably 1600 HV or less.

In order to keep the Vickers hardness within the above range, it is preferable to produce the protective film by the method described below (the present production method).

The Vickers hardness of the protective film is determined in accordance with JIS Z 2244 (2009).

More specifically, the Vickers hardness is a Vickers hardness (HV 0.005) determined using a micro Vickers hardness tester (HM-220, manufactured by Mitutoyo Corporation) when a test force of 4.9 mN (0.049 N) is applied by a diamond indenter having a facing angle of 136°.

### Heat Resistance Temperature

The heat resistance temperature of the present protective film is preferably 300° C. or higher, more preferably 350° C. or higher, still more preferably 450° C. or higher, yet still more preferably 550° C. or higher, particularly preferably 650° C. or higher, and most preferably 750° C. or higher.

In order to keep the heat resistance temperature within the above range, it is preferable to produce the protective film by the method described below (the present production method).

The heat resistance temperature of the protective film is determined by performing the following test (heat resistance test).

First, a sample of a member including a protective film is heated at a temperature rising rate of 300° C./hr using an atmospheric firing furnace, heated at any temperature T1 for 1 hour, and cooled at 50° C./hr, and the sample is taken out. Thereafter, the presence or absence of cracks in the protective film is checked using an optical microscope.

Such a heat resistance test is performed at a temperature T1 (at intervals of 50° C.) from 100° C. to 800° C., and the maximum temperature T1 at which no crack occurs is defined as the heat resistance temperature of the protective film.

### <<Porosity>>

For the reason that the present protective film has excellent heat resistance and excellent plasma resistance, the porosity of the present protective film is preferably less than 2.0 volume %, more preferably 1.5 volume % or less, still more preferably 1.0 volume % or less, yet still more preferably 0.5 volume % or less, particularly preferably 0.3 volume % or less, even still more preferably 0.2 volume % or less, and most preferably 0.1 volume % or less.

In order to keep the porosity within the above range, it is preferable to produce the protective film by the method described below (the present production method).

The porosity of the protective film is determined as follows.

First, a focused ion beam (FIB) is used to perform slope processing on a part of the member including a protective film in a thickness direction at an angle of 520 from a surface of the protective film toward the substrate to expose a cross section. The exposed cross section is observed at a magnification of 20000 times using a field emission scanning electron microscope (FE-SEM), and a cross-sectional image thereof is captured.

The cross-sectional image is captured at a plurality of locations. Specifically, for example, when the protective film has a circular shape, images are captured at five points in total, one point at a center of the surface of the protective film (or a surface of the substrate) and four points at positions that are 10 mm away from the outer periphery, and a size of the cross-sectional image is 6 μm×5 μm. When a thickness of the protective film is 5 μm or more, cross-sectional images are respectively captured at a plurality of imaging positions so that the entire cross section of the protective film can be observed in the thickness direction.

Subsequently, an area of the pore portion in the cross-sectional image is specified by analyzing the obtained cross-sectional image using image analysis software (Image J, manufactured by National Institute of Health). A proportion of the area of the pore portion to the area of the entire cross section of the protective film is calculated and regarded as the porosity (unit: volume %) of the protective film. Regarding pores that are too fine to be detected by the image analysis software (pores with a pore diameter of 20 nm or less), areas thereof are regarded as 0.

### <<Composition>>

The present protective film preferably includes yttrium oxides or yttrium oxyfluorides.

Hereinafter, the present protective film in each case will be described.

### (Yttrium Oxides)

First, a case where the present protective film includes yttrium oxide (Y₂O₃) will be described.

In this case, a content of Y₂O₃ in the present protective film is preferably 95 mass % or more, more preferably 98 mass % or more, and still more preferably 100 mass %.

The protective film produced using only Y₂O₃ as an evaporation source by the method (the present production method) described below is substantially made of only Y₂O₃, and the Y₂O₃ content thereof satisfies the above range.

### ((Degree of Orientation))

When the area of the protective film is increased, from the viewpoint of preventing the occurrence of cracks (including wrinkles; the same applies below) in the protective film, it is preferable that the degree of orientation of the (222) plane of Y₂O₃ in the protective film (hereinafter, also simply referred to as “degree of orientation”) is high.

In addition, as the degree of orientation of the protective film is higher, stress is not randomly generated when heated, and the heat resistance is improved.

Therefore, the degree of orientation of the present protective film is preferably 50% or more, more preferably 65% or more, still more preferably 80% or more, yet still more preferably 85% or more, particularly preferably 90% or more, more particularly preferably 95% or more, even more preferably 98% or more, and most preferably 99% or more.

In order to keep the degree of orientation within the above range, it is preferable to produce the protective film by the method described below (the present production method).

The degree of orientation is the proportion (unit:%) of a peak intensity of the (222) plane when the total of the peak intensities of the respective surfaces of Y₂O₃ in the XRD pattern of the protective film is 100.

The XRD pattern of the protective film (and the stress-relaxation layer and the base layer, which will be described below) is obtained by performing an XRD measurement in a micro portion 2D (two-dimensional) mode using an X-ray diffractometer (D8 DISCOVER Plus, manufactured by Bruker) under the following conditions.
X-ray source: CuKα ray (output: 45 kV, current: 120 mA)
Scanning range: 2θ=10° to 80°
Step time: 0.2 s/step
Scan speed: 10°/min
Step width: 0.02°
Detector: multi-mode detector EIGER (2D mode)
Incident side optical system: multilayer mirror+1.0 mmφ micro slit+1.0 mmφ collimator
Light receiving side optical system: OPEN

### (Yttrium Oxyfluoride)

Next, a case where the present protective film includes yttrium oxyfluorides will be described.

Examples of a chemical formula representing yttrium oxyfluorides include YOF and Y₅O₄F₇. YOF is an oblique crystal having a low hardness, whereas Y₅O₄F₇ has a special crystal structure called a rhombohedron and has a high hardness.

It is preferable that the present protective film has a large proportion of Y₅O₄F₇ having a rhombohedral crystal structure. That is, it is preferable that a peak intensity ratio of Y₅O₄F₇ in the X-ray diffraction pattern is equal to or larger than a certain value. Accordingly, the present protective film is hard and exhibits a Vickers hardness equal to or larger than a certain value.

Further, the present protective film is dense and has a low porosity when being formed by a method described below (the present production method).

### ((Peak Intensity Ratio))

The peak intensity ratio of Y₅O₄F₇ in the X-ray diffraction pattern of the present protective film (hereinafter, also referred to as “Y₅O₄F₇ peak intensity ratio” or simply “peak intensity ratio”) is 60% or more, preferably 80% or more, more preferably 90% or more, still more preferably 95% or more, yet still more preferably 98% or more, particularly preferably 99% or more, and most preferably 100%.

In order to keep the Y₅O₄F₇ peak intensity ratio within the above range, it is preferable to produce the protective film by the method described below (the present production method).

The Y₅O₄F₇ peak intensity ratio is a proportion (unit: %) of a main peak intensity of Y₅O₄F₇ when the total of the main peak intensities of crystal phases shown below is 100 in the X-ray diffraction (XRD) pattern of the protective film.

As for the main peak of each crystal phase, a main peak of Y₅O₄F₇ appears in a vicinity of 2θ=28.1°, a main peak of Y₂O₃ appears in a vicinity of 2θ=29.2°, and a main peak of YOF appears in a vicinity of 2θ=29.2°.

At the main peak position of Y₅O₄F₇, the peak of Y₆O₅F₈ crystal and the peak of Y₇O₆F₉ crystal appear in an overlapping manner. Furthermore, the main peak of YF₃ also appears overlapping the main peak position of Y₅O₄F₇.

The peaks at the main peak position of Y₅O₄F₇ are all treated as peaks of Y₅O₄F₇.

When the YF₃ crystal is present, an intensity of a peak in a vicinity of 2θ=24.5°, which is a second main peak of the YF₃ crystal, is multiplied by 1.3 and converted to be equivalent to a main peak, and this peak intensity is defined as the main peak intensity of YF₃. At this time, an intensity of the second main peak of the YF₃ crystal converted by being multiplied by 1.3 is subtracted from the intensity of the peak of Y₅O₄F₇ (a peak located at the main peak position of Y₅O₄F₇). If the intensity (relative intensity) of the second main peak of the YF₃ crystal is “2.0” and the intensity (relative intensity) of the peak at the main peak position of Y₅O₄F₇ is “6.0”, the intensity of the second main peak of the YF₃ crystal is converted into “2.6” (=2.0×1.3). Therefore, the intensity of the peak at the main peak position of Y₅O₄F₇ is subtracted by the converted intensity of the second main peak of the YF₃ crystal to obtain “3.4” (=6.0-2.6).

The XRD pattern of the protective film is obtained by performing an XRD measurement in a micro portion 2D (two-dimensional) mode using an X-ray diffractometer (D8 DISCOVER Plus, manufactured by Bruker) under the above-described conditions.

### ((Content of Each Element))

The present protective film includes yttrium (Y), oxygen (O), and fluorine (F) when the present protective film includes yttrium oxyfluorides.

Here, the content of Y in the present protective film is preferably 20 atom % or more, more preferably 25 atom % or more, still more preferably 26 atom % or more, particularly preferably 27 atom % or more, and most preferably 27.5 atom % or more.

On the other hand, the content of Y in the present protective film is preferably 35 atom % or less, more preferably 30 atom % or less, still more preferably 29 atom % or less, and particularly preferably 28 atom % or less.

Here, the content of O in the present protective film is preferably 20 atom % or more, more preferably 21 atom % or more, still more preferably 22 atom % or more, particularly preferably 23 atom % or more, and most preferably 24 atom % or more.

On the other hand, the content of O in the present protective film is preferably 35 atom % or less, more preferably 30 atom % or less, still more preferably 28 atom % or less, particularly preferably 26 atom % or less, and most preferably 25 atom % or less.

Here, the content of F in the present protective film is preferably 35 atom % or more, more preferably 40 atom % or more, still more preferably 44 atom % or more, particularly preferably 47 atom % or more, and most preferably 48 atom % or more.

On the other hand, the content of F in the present protective film is preferably 60 atom % or less, more preferably 55 atom % or less, still more preferably 52 atom % or less, yet still more preferably 50 atom % or less, particularly preferably 49.5 atom % or less, and most preferably 49 atom % or less.

In order to keep the content of each element within the above range, for example, in the method described below (the present production method), production conditions such as the amount of the evaporation source are appropriately adjusted.

The content (unit: atom %) of each element in the protective film is measured using an energy dispersive X-ray spectrometer (EX-250SE, manufactured by Horiba, Ltd.).

### ((Degree of Orientation))

When the area of the protective film is increased, from the viewpoint of preventing the occurrence of cracks in the protective film, it is preferable that the degree of orientation of the (151) plane of Y₅O₄F₇ in the protective film (hereinafter, also simply referred to as “degree of orientation”) is high.

In addition, as the degree of orientation of the protective film is higher, stress is not randomly generated when heated, and the heat resistance is improved.

As an index of the degree of orientation, the half width of a rocking curve of the (151) plane of Y₅O₄F₇ is used. Specifically, the rocking curve of a peak of the (151) plane of Y₅O₄F₇, which is obtained by using a two-dimensional mode detector, is integrated in a 20 direction, and the orientation is evaluated using its half width. The smaller the half width (unit: °) is, the higher the degree of orientation is.

The half width of the rocking curve of the (151) plane of Y₅O₄F₇ is preferably 400 or less, more preferably 300 or less, still more preferably 250 or less, yet still more preferably 200 or less, particularly preferably 150 or less, and most preferably 100 or less.

In order to keep the degree of orientation within the above range, it is preferable to produce the protective film by the method described below (the present production method).

### Crystallite Size

As described above, for example, the particles falling off from the member exposed to the plasma may adhere to a semiconductor substrate and become a foreign substance causing a defect in a circuit.

At this time, as the sizes of the particles are small, the occurrence of defects can be prevented.

Therefore, the crystallite size of the present protective film is preferably 40 nm or less, more preferably 30 nm or less, still more preferably 20 nm or less, yet still more preferably 15 nm or less, particularly preferably 11 nm or less, particularly preferably 10 nm or less, even still more preferably 9 nm or less, and most preferably 8 nm or less.

On the other hand, as the crystallite size of the protective film increases, the change in the crystallite size when heated is small and stable, and the heat resistance is improved.

Therefore, for the reason that the present protective film has more excellent heat resistance, the crystallite size of the present protective film is preferably 2 nm or more, more preferably 6 nm or more, still more preferably 7 nm or more, and particularly preferably 10 nm or more.

In order to keep the crystallite size within the above range, it is preferable to produce the protective film by the method described below (the present production method).

The crystallite size of the protective film is determined using Scherrer's formula based on data of XRD pattern data obtained by the XRD measurement of the mirror-polished protective film.

### <<Thickness>>

The thickness of the present protective film is preferably 0.3 μm or more, more preferably 1.0 μm or more, still more preferably 1.5 μm or more, yet still more preferably 5 m or more, and particularly preferably 10 μm or more. The thickness of the present protective film may be 15 μm or more.

On the other hand, the thickness of the present protective film is preferably 300 μm or less, more preferably 200 μm or less, still more preferably 100 μm or less, yet still more preferably 50 μm or less, particularly preferably 30 μm or less, and most preferably 15 μm or less. The thickness of the present protective film may be 10 μm or less.

The thickness of the protective film is measured as follows.

The cross section of the protective film is observed using a scanning electron microscope (SEM), the thickness of the protective film is measured at any five points, and an average value of the thickness of the measured five points is regarded as the thickness (unit: m) of the protective film.

### <<Number of Hydrogen Atoms

The number of hydrogen atoms in the present protective film is preferably small. Accordingly, the plasma resistance of the present protective film is more excellent.

The reasons for this are presumed to be as follows. That is, when the amount of hydrogen in the protective film is large, the hydrogen easily reacts with fluorine contained in the plasma (or the gas used to generate the plasma), and as a result, the protective film is likely to be damaged. On the other hand, when the amount of hydrogen in the protective film is small, the reaction with fluorine is relatively reduced, and damage to the protective film is prevented.

Specifically, the number of hydrogen atoms in the present protective film (number of hydrogen atoms in the film) is preferably 5.0×10²¹ atoms/cm³ or less, more preferably 4.5×10²¹ atoms/cm³ or less, still more preferably 3.5×10²¹ atoms/cm³ or less, yet still more preferably 3.0×10²¹ atoms/cm³ or less, particularly preferably 2.5×10²¹ atoms/cm³ or less, and most preferably 2.3×10²¹ atoms/cm³ or less.

Hydrogen in the protective film is highly likely due to the moisture contained in the substrate described below.

In particular, when the material of the substrate is ceramic, the number of hydrogen atoms in the protective film to be formed can be reduced by heating (preheating) the substrate before forming the protective film.

In addition, a method for reducing the number of hydrogen atoms in the protective film will be described below.

On the other hand, the number of hydrogen atoms in the present protective film is preferably 0.1×10²¹ atoms/cm³ or more, and more preferably 0.5×10²¹ atoms/cm³ or more.

The number of hydrogen atoms in the protective film is determined using a secondary ion mass spectrometer (model IMS-6f, manufactured by AMETEK, Inc.) under the conditions of primary ion species Cs⁺, a primary acceleration voltage of 15.0 kV, and a detection region of φ8 μm and a measurement depth of 500 nm.

### <<Compressive Stress>>

The stress (internal stress, residual stress) of the present protective film is preferably not a tensile stress but a compressive stress.

The compressive stress of the present protective film is preferably 700 MPa or more, more preferably 1000 MPa or more, and still more preferably 1200 MPa or more.

On the other hand, the compressive stress of the present protective film is preferably 1700 MPa or less, more preferably 1600 MPa or less, and still more preferably 1500 MPa or less.

The compressive stress of the protective film is determined as follows.

A protective film is formed on a quartz glass substrate, a surface shape of the formed protective film is measured using a surface shape measurement apparatus (SURFCOM NEX 241 SD2-13, manufactured by Tokyo Seimitsu Co., Ltd.), and the compressive stress (film stress σ) of the protective film is determined based on the Stoney equation (the following equation).

The Stoney equation is expressed as follows.

$$σ = {Yd}^{2} / ( 6 c ( 1 - v ) t )$$

In the above formula, σ: film stress, Y: Young's modulus of substrate, d: thickness of substrate, v: Poisson's ratio of substrate, t: protective film thickness, and c: radius of curvature.

### <Substrate>

The substrate has at least a surface on which a stress-relaxation layer (or a base layer described below) is formed. Hereinafter, this surface may be referred to as a “film formation surface” for convenience.

### <<Material>>

A material of the substrate is appropriately selected depending on the use of the member or the like.

The substrate is formed of, for example, at least one selected from the group consisting of carbon (C), ceramic, and metal.

Here, the ceramic is preferably, for example, at least one selected from the group consisting of glass (soda lime glass or the like), quartz, aluminum oxide (Al₂O₃), aluminum nitride (AlN), cordierite, yttrium oxide, silicon carbide (SiC), Si-impregnated silicon carbide, silicon nitride (SiN), sialon, and aluminum oxynitride (AlON). As the ceramic, aluminum oxide or quartz is more preferable.

The Si-impregnated silicon carbide is obtained by heating and melting elemental Si and impregnating silicon carbide (SiC) with the molten Si.

It is preferable that the metals are, for example, at least one selected from the group consisting of aluminum (Al) and an alloy containing aluminum (Al).

### <<Shape>>

The shape of the substrate is not particularly limited, and examples thereof include a flat plate shape, a ring shape, a dome shape, a protruding shape, and a recessed shape. The shape of the substrate is appropriately selected depending on the use of the member.

### <<Surface Roughness of Film Formation Surface

As the surface roughness of the film formation surface of the substrate is smaller, the yttrium-based protective film formed on the film formation surface is denser and harder, cracks are less likely to occur even when heated (particularly, repeatedly heated), and heat resistance is more excellent.

Therefore, the surface roughness of the film formation surface of the substrate is, in terms of the arithmetic average roughness Ra, preferably less than 4.5 μm, more preferably 2.0 μm or less, still more preferably 1.0 μm or less, yet still more preferably 0.5 μm or less, particularly preferably 0.20 μm or less, and most preferably 0.12 μm or less.

On the other hand, the surface roughness of the film formation surface of the substrate is preferably 0.001 μm or more, more preferably 0.01 μm or more, and still more preferably 0.08 μm or more as the arithmetic average roughness Ra.

The surface roughness (arithmetic average roughness Ra) of the film formation surface is measured in accordance with JIS B 0601: 2001.

### <<Maximum Length of Film Formation Surface>>

The maximum length of the film formation surface of the substrate is preferably 30 mm or more, more preferably 100 mm or more, still more preferably 200 mm or more, yet still more preferably 300 mm or more, particularly preferably 500 mm or more, very preferably 800 mm or more, and most preferably 1000 mm or more.

The term “maximum length” means the maximum length that the film formation surface has. Specifically, for example, when the film formation surface is a circle in plan view, the maximum length is the diameter of the circle. When the film formation surface is a ring in plan view, the maximum length is the outer diameter thereof. When the film formation surface is a rectangle in plan view, the maximum length is the length of the maximum diagonal line.

On the other hand, the maximum length of the film formation surface is preferably 2000 mm or less, and more preferably 1500 mm or less.

FIG. 2 is a schematic diagram illustrating a ring-shaped substrate 5 with a half cut away.

For example, when the substrate 5 shown in FIG. 2 has an outer diameter D₁ of 100 mm, an inner diameter D₂ of 90 mm, and a thickness t of 5 mm, the maximum length of the substrate 5 is 100 mm.

The substrate 5 has a film formation surface 7, and as shown in FIG. 2, the film formation surface 7 may have a first film formation surface 7a defining the maximum length (outer diameter D₁) and a second film formation surface 7b different from the first film formation surface 7a.

It is preferable that a proportion of the area of the second film formation surface 7b to the total area of the film formation surface 7 is, for example, 60% or less.

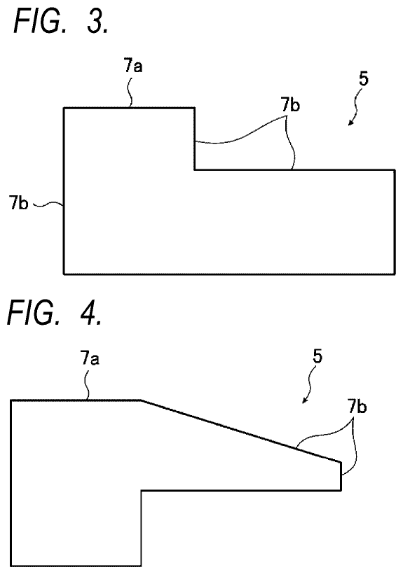

FIG. 3 is a schematic diagram illustrating a part of a cross section of another ring-shaped substrate 5.

As shown in FIG. 3, the substrate 5 may have a plurality of second film formation surfaces 7b.

FIG. 4 is a schematic diagram illustrating a part of a cross section of still another ring-shaped substrate 5.

It is preferable that an angle formed by the first film formation surface 7a and the second film formation surface 7b is, for example, 200 to 120°. In the substrate 5 shown in FIG. 4, an angle formed by the first film formation surface 7a and the second film formation surface 7b connected to the first film formation surface 7a is about 30°.

### <Stress-Relaxation Layer>

As described above, at least one stress-relaxation layer is disposed between the substrate and the yttrium-based protective film (present protective film). Accordingly, the present protective film has excellent heat resistance. This is presumably because the stress (tensile stress) of the present protective film is relaxed by the stress-relaxation layer.

### <<Number of Layers>>

The upper limit of the number of the stress-relaxation layers is not particularly limited, and the number of the base layers is preferably 5 or less, more preferably 4 or less, still more preferably 3 or less, particularly preferably 2 or less, and most preferably 1.

### <<Composition>>

The stress-relaxation layer preferably includes, for example, at least one oxide selected from the group consisting of Al₂O₃ (including “β-Al₂O₃”, the same applies hereinafter), SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃ (referred to as “group G” for convenience).

The stress-relaxation layer preferably includes at least two oxides selected from the group G.

The group G preferably consists of Al₂O₃, SiO₂, Y₂O₃, MgO, CaO, SrO, B₂O₃, and ZrO₂, more preferably consists of Al₂O₃, SiO₂, Y₂O₃, MgO, CaO, SrO, and B₂O₃, and still more preferably consists of Al₂O₃, SiO₂, and Y₂O₃.

When the stress-relaxation layer includes only one oxide (for example, Al₂O₃), the content of the oxide (for example, Al₂O₃) in the stress-relaxation layer is preferably 100 mol %.

For example, when the material of the substrate is aluminum nitride (AlN), the stress-relaxation layer in contact with the substrate preferably includes only one oxide (for example, Al₂O₃, MgO, or ZrO₂).

The content of Al₂O₃ in the stress-relaxation layer is preferably 0 mol % or more, more preferably 5 mol % or more, still more preferably 10 mol % or more, yet still more preferably 15 mol % or more, particularly preferably 20 mol % or more, extremely preferably 25 mol % or more, and most preferably 30 mol % or more.

On the other hand, the content of Al₂O₃ in the stress-relaxation layer is preferably 70 mol % or less, more preferably 60 mol % or less, still more preferably 50 mol % or less, yet still more preferably 45 mol % or less, particularly preferably 40 mol % or less, and most preferably 35 mol % or less.

The content of SiO₂ in the stress-relaxation layer is preferably 0 mol % or more, more preferably 20 mol % or more, still more preferably 30 mol % or more, yet still more preferably 40 mol % or more, particularly preferably 45 mol % or more, and most preferably 50 mol % or more.

On the other hand, the content of SiO₂ in the stress-relaxation layer is preferably 90 mol % or less, more preferably 85 mol % or less, still more preferably 80 mol % or less, yet still more preferably 75 mol % or less, particularly preferably 70 mol % or less, extremely preferably 65 mol % or less, even still more preferably 60 mol % or less, and most preferably 55 mol % or less.

The content of Y₂O₃ in the stress-relaxation layer is preferably 0 mol % or more, more preferably 5 mol % or more, still more preferably 10 mol % or more, yet still more preferably 13 mol % or more, particularly preferably 16 mol % or more, and most preferably 19 mol % or more.

On the other hand, the content of Y₂O₃ in the stress-relaxation layer is preferably 60 mol % or less, more preferably 40 mol % or less, still more preferably 30 mol % or less, particularly preferably 25 mol % or less, and most preferably 20 mol % or less.

When the stress-relaxation layer includes Al₂O₃, SiO₂, and Y₂O₃, the content of oxides other than Al₂O₃, SiO₂, and Y₂O₃ (for example, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃) in the stress-relaxation layer is preferably 20 mol % or less, more preferably 10 mol % or less, still more preferably 5 mol % or less, particularly preferably 1 mol % or less, and most preferably 0 mol % or less.

When the stress-relaxation layer includes SiO₂ and Y₂O₃, a molar ratio of SiO₂ to Y₂O₃(SiO₂/Y₂O₃) is preferably 90/10 to 20/80, more preferably 80/20 to 30/70, and still more preferably 70/30 to 40/60.

At this time, the content of oxides other than SiO₂ and Y₂O₃ (for example, Al₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃) is preferably 10 mol % or less, more preferably 5 mol % or less, still more preferably 1 mol % or less, and particularly preferably 0 mol %.

The content (unit: mol %) of each oxide in the stress-relaxation layer is measured using an energy dispersive X-ray spectrometer (EX-250SE, manufactured by Horiba, Ltd.).

For example, when a molar ratio of Y, Al, and Si (Y/Al/Si) is 25/25/50 and no element other than Y, Al, Si, and O is detected, the content of Y₂O₃ is 25 mol %, the content of Al₂O₃ is 25 mol %, and the content of SiO₂ is 50 mol %.

The same applies to the base layer described below.

### State of Layer

The stress-relaxation layer is preferably an amorphous layer.

However, the stress-relaxation layer, which is an amorphous layer, may contain crystals.

### <<Thermal Stability Temperature>>

The thermal stability temperature of the stress-relaxation layer is preferably 300° C. or higher, more preferably 350° C. or higher, still more preferably 400° C. or higher, and particularly preferably 450° C. or higher.

The thermal stability temperature of the stress-relaxation layer is determined by performing the following test.

First, a sample including a stress-relaxation layer (no yttrium-based protective film) on quartz is prepared. Next, the prepared sample is heated at a temperature rising rate of 300° C./hr using an atmospheric firing furnace, heated at any temperature T2 for 1 hour, and cooled at 50° C./hr, and the sample is taken out. Thereafter, an XRD measurement of the sample is performed to check whether crystals are generated.

Such a test is performed at the temperature T2 (at intervals of 50° C.) from 100° C. to 500° C., and the maximum temperature T2 at which no crystal is formed is defined as the thermal stability temperature of the stress-relaxation layer.

### <<Thickness>>

The thickness of each stress-relaxation layer is preferably 0.05 μm or more, more preferably 0.5 μm or more, still more preferably 0.8 μm or more, yet still more preferably 1.1 m or more, particularly preferably 1.4 μm or more, even still more preferably 1.7 μm or more, and most preferably 2.0 μm or more.

On the other hand, the thickness of each stress-relaxation layer is preferably 9.0 μm or less, more preferably 5.0 μm or less, still more preferably 7.0 μm or less, and particularly preferably 3.0 μm or less.

The thickness of the stress-relaxation layer is measured in the same manner as the thickness of the yttrium-based protective film.

### <Base Layer>

As described above, at least one base layer may be disposed between the substrate and the stress-relaxation layer.

By forming the base layer, the tensile stress of the yttrium-based protective film is relaxed to generate the compressive stress, or the adhesion of the yttrium-based protective film to the substrate is increased.

Among the plurality of layers constituting the stress-relaxation layer, one layer or two or more layers on a substrate side may be regarded as the base layer.

That is, the base layer may be a layer different from the stress-relaxation layer, or may be at least a part of the stress-relaxation layer.

### <<Number of Layers>>

The upper limit of the number of the base layers is not particularly limited, and the number of the base layers is preferably 5 or less, more preferably 4 or less, still more preferably 3 or less, particularly preferably 2 or less, and most preferably 1.

### <<State of Layer>>

The base layer is preferably an amorphous layer or a microcrystalline layer (amorphous layer containing crystals).

### <<Composition>>

When the base layer is at least one layer of the stress-relaxation layer, the composition of the base layer is preferably the same as that described above for the stress-relaxation layer.

On the other hand, when the base layer is a layer different from the stress-relaxation layer, the base layer preferably includes at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

The base layer more preferably includes SiO₂, or includes at least two oxides selected from the group consisting of Al₂O₃, SiO₂, and Y₂O₃.

When two or more base layers are disposed between the substrate and the yttrium-based protective film, the oxides in the base layers are preferably different from each other between the adjacent base layers.

Specific examples of the case where the oxides in the adjacent base layers are different from each other include a case where an oxide in a base layer 1 is “SiO₂”, an oxide in a base layer 2 is “Al₂O₃+SiO₂”, and an oxide in a base layer 3 is “Al₂O₃”.

### <<Thickness>>

The thickness of the base layer is preferably 0.05 μm or more, more preferably 0.1 m or more, still more preferably 0.2 μm or more, yet still more preferably 0.5 μm or more, particularly preferably 0.8 μm or more, and most preferably 1.1 μm or more.

On the other hand, the thickness of the base layer is preferably 15.0 μm or less, more preferably 10.0 μm or less, still more preferably 7.0 μm or less, particularly preferably 5.0 μm or less, and most preferably 3.0 μm or less.

The thickness of the base layer is measured in the same manner as the thickness of the yttrium-based protective film.

### <Use of Member>

The present member is used as, for example, a member such as a top plate in a semiconductor device producing apparatus (a plasma etching apparatus, a plasma CVD apparatus, or the like).

However, the use of the present member is not limited thereto.

### [Method for Producing Member]

Next, a method for producing the member according to the present embodiment (hereinafter, also referred to as “the present production method” for convenience) will be described.

The present production method is a so-called ion assisted deposition (IAD) method.

Schematically, an evaporation source (Y₂O₃, YF₃, etc.) is caused to evaporate and adhere to the substrate while emitting ions in a vacuum, thereby forming the yttrium-based protective film.

According to the present production method, the yttrium-based protective film can be formed very densely. That is, the obtained yttrium-based protective film has a low porosity. The crystallite size is also small.

When the stress-relaxation layer is formed, the yttrium-based protective film is less likely to crack even when heated at a high temperature, and has excellent heat resistance because the tensile stress is relaxed.

The surface roughness (arithmetic average roughness Ra) of the film formation surface of the substrate is preferably within the above-described range. Accordingly, the formed yttrium-based protective film is denser and harder, and is less likely to crack.

In a method such as a thermal spraying method, an aerosol deposition (AD) method, or an ion plating (IP) method, a large number of pores are likely to remain in the obtained yttrium-based protective film.

### <Apparatus Configuration>

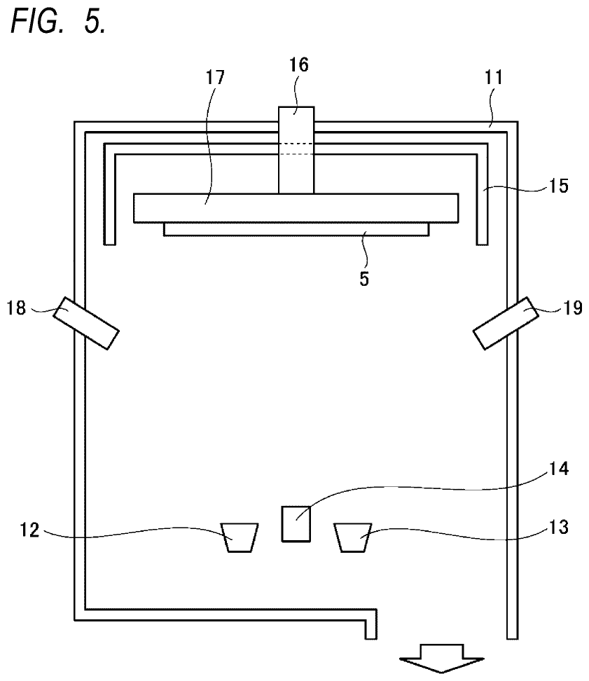

The present production method will be described in more detail with reference to FIG. 5.

FIG. 5 is a schematic diagram illustrating an apparatus used for producing the yttrium-based protective film.

The apparatus shown in FIG. 5 includes a chamber 11. A vacuum state can be formed inside the chamber 11 by driving a vacuum pump (not shown) to evacuate.

Crucibles 12 and 13, and an ion gun 14 are disposed inside the chamber 11, and a holder 17 is disposed above the crucible 12, the crucible 13, and the ion gun 14.

The holder 17 is integrated with a support shaft 16 and rotates with the rotation of the support shaft 16. A heater 15 is disposed around the holder 17.

The above-described substrate 5 is held by the holder 17 in a state in which the film formation surface of the substrate 5 faces downward. The substrate 5 held by the holder 17 rotates with the rotation of the holder 17 while being heated by the heater 15.

Further, crystal type film thickness monitors 18 and 19 are attached to the chamber 11.

### <Formation of Yttrium-Based Protective Film (Part 1)>

A case where the yttrium-based protective film (not shown in FIG. 5) including yttrium oxide (Y₂O₃) is formed on the substrate 5 in the apparatus shown in FIG. 5 will be described.

First, one or both of the crucibles 12 and 13 is/are filled with the evaporation source Y₂O₃.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ in one or both of the crucibles 12 and 13 is evaporated while emitting ions (ion beams) from the ion gun 14.

The ions emitted by the ion gun 14 are preferably ions of at least one element selected from the group consisting of oxygen, argon, neon, krypton, and xenon.

The evaporation source melts and evaporates by being irradiated with electron beams (not shown).

In this way, the evaporated evaporation source adheres to the substrate 5 (the film formation surface thereof) to form an yttrium-based protective film including yttrium oxide (Y₂O₃).

### <<Internal Pressure of Chamber>>

The film formation is performed in the vacuum, and specifically, the internal pressure of the chamber 11 is preferably 6×10⁻² Pa or less, more preferably 5×10⁻² Pa or less, and still more preferably 3×10⁻² Pa or less.

On the other hand, the internal pressure of the chamber 11 is preferably more than 1×10⁻⁶ Pa, more preferably 1×10⁻⁵ Pa or more, and still more preferably 1×10⁻⁴ Pa or more.

### <<Temperature of Substrate>>

During the film formation, for the reason that the formed yttrium-based protective film has more excellent heat resistance, the temperature of the substrate 5 heated by the heater 15 is preferably 200° C. or higher, more preferably 270° C. or higher, still more preferably 320° C. or higher, particularly preferably 370° C. or higher, and most preferably 400° C. or higher.

On the other hand, the temperature is preferably 600° C. or lower, more preferably 500° C. or lower, and still more preferably 450° C. or lower.

### Film Formation Rate

The rates (film formation rate) at which films are formed by evaporating the evaporation sources in the crucibles 12 and 13 are respectively monitored in advance using the crystal type film thickness monitors 18 and 19.

The film formation rate is adjusted by controlling conditions of the electron beam emitted to the evaporation source and conditions (current value, current density, etc.) of the ion beam of the ion gun 14.

During the formation of the yttrium-based protective film, the film formation rate (unit: nm/min) of each evaporation source is adjusted to a desired value.

The film formation rate of the evaporation source Y₂O₃ is preferably 1 nm/min or more, more preferably 1.5 nm/min or more, and still more preferably 2 nm/min or more.

The film formation rate of the evaporation source Y₂O₃ is preferably 20 nm/min or less, more preferably 15 nm/min or less, still more preferably 10 nm/min or less, yet still more preferably 5 nm/min or less, particularly preferably 3.5 nm/min or less, and most preferably 2.1 nm/min or less.

### <<Conditions of Ion Irradiation>>

The distance between the ion gun 14 and the substrate 5 is preferably 700 mm or more, and more preferably 900 mm or more. On the other hand, the distance is preferably 1500 mm or less, and more preferably 1300 mm or less.

The ion beam current value is preferably 1000 mA or more, and more preferably 1500 mA or more. On the other hand, the ion beam current value is preferably 3000 mA or less, and more preferably 2500 mA or less.

For the reason that the obtained yttrium-based protective film becomes harder, the ion beam current density is preferably 40 μA/cm² or more, more preferably 65 μA/cm² or more, still more preferably 75 μA/cm² or more, and particularly preferably 77 μA/cm² or more.

On the other hand, the ion beam current density is preferably 140 μA/cm² or less, more preferably 120 μA/cm² or less, and still more preferably 100 μA/cm² or less.

### <Formation of Yttrium-Based Protective Film (Part 2)>

Next, a case where the yttrium-based protective film (not shown in FIG. 5) including yttrium oxyfluoride is formed on the substrate 5 will be described.

First, one crucible 12 is filled with an evaporation source Y₂O₃, and the other crucible 13 is filled with an evaporation source YF₃.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ in the crucible 12 and the evaporation source YF₃ in the crucible 13 are evaporated in parallel while emitting ions (ion beams) from the ion gun 14.

The ions emitted by the ion gun 14 are preferably ions of at least one element selected from the group consisting of oxygen, argon, neon, krypton, and xenon.

The evaporation source melts and evaporates by being irradiated with electron beams (not shown).

In this way, the evaporated evaporation source adheres to the substrate 5 (more specifically, a surface of the stress-relaxation layer described below) to form an yttrium-based protective film including yttrium oxyfluoride.

### <<Film Formation Rate>>

A film formation rate ratio (Y₂O₃/YF₃) of the film formation rate (unit: nm/min) of the evaporation source Y₂O₃ to the film formation rate (unit: nm/min) of the evaporation source YF₃ is preferably 1/9.5 or more, more preferably 1/8.0 or more, still more preferably 1/6.0 or more, and particularly preferably 1/4.5 or more.

On the other hand, the film formation rate ratio (Y₂O₃/YF₃) is preferably 1/1.1 or less, more preferably 1/1.3 or less, still more preferably 1/1.8 or less, and particularly preferably 1/2.5 or less.

A total rate of the film formation rate of the evaporation source Y₂O₃ and the film formation rate of the evaporation source YF₃ is preferably 5 nm/min or more, more preferably 8 nm/min or more, and still more preferably 10 nm/min or more. On the other hand, the total rate is preferably 50 nm/min or less, more preferably 35 nm/min or less, and still more preferably 20 nm/min or less.

### <<Internal Pressure of Chamber, Temperature of Substrate, and Ion Irradiation Conditions>>

The internal pressure of the chamber, the temperature of the substrate, and the ion irradiation conditions when forming the yttrium-based protective film including yttrium oxyfluoride conform to a case where the yttrium-based protective film including yttrium oxide (Y₂O₃) is formed.

### <Formation of Stress-Relaxation Layer>

Before the yttrium-based protective film is formed, the above-described stress-relaxation layer (for example, the stress-relaxation layer 8 and the stress-relaxation layer 9) is preferably formed on the film formation surface of the substrate 5.

Similarly to the yttrium-based protective film, the stress-relaxation layer is formed by ion assisted deposition.

For example, when a stress-relaxation layer including Y₂O₃ and SiO₂ is formed, the crucible 12 is filled with Y₂O₃ as an evaporation source, the crucible 13 is filled with SiO₂ as an evaporation source, and the evaporation source is evaporated while emitting ions (ion beams) from the ion gun 14 to adhere the evaporation source to the film formation surface of the substrate 5.

When a stress-relaxation layer including three or more kinds of oxides is formed, another crucible and a crystal type film thickness monitor (neither of which are shown) are then disposed in the chamber 11 to form a stress-relaxation layer.

For example, when a stress-relaxation layer including Y₂O₃, SiO₂, and Al₂O₃ is formed, the crucible 12 is filled with Y₂O₃ as an evaporation source, the crucible 13 is filled with SiO₂ as an evaporation source, another crucible (not shown) is further filled with Al₂O₃ as an evaporation source, and the evaporation source is evaporated while emitting ions (ion beams) from the ion gun 14 to adhere the evaporation source to the film formation surface of the substrate 5.

Conditions for forming the stress-relaxation layer conform to the conditions for forming the yttrium-based protective film.

### <Formation of Base Layer>

Before the yttrium-based protective film is formed, the above-described base layer (for example, the base layer 1, the base layer 2, and the base layer 3) is preferably formed on the film formation surface of the substrate 5.

Similarly to the yttrium-based protective film, the base layer is formed by ion assisted deposition.

For example, when a base layer made of Al₂O₃ is formed, one or both of the crucible 12 and the crucible 13 is/are filled with Al₂O₃ as an evaporation source, and the evaporation source is evaporated while emitting ions (ion beams) from the ion gun 14 to adhere the evaporation source to the film formation surface of the substrate 5.

Conditions for forming the base layer conform to the conditions for forming the yttrium-based protective film.

Here, the substrate may contain water of crystallization.

For example, when the temperature of a substrate made of aluminum oxide (Al₂O₃) is increased from room temperature, the generation of water of crystallization due to a hydrate which is a low-temperature stable phase of aluminum oxide (for example, boehmite y alumina) is observed at a temperature around 520° C.

When moisture caused by the water of crystallization of the substrate is contained in the formed yttrium-based protective film, the number of hydrogen atoms in the yttrium-based protective film is likely to increase.

Therefore, before the evaporation source Y₂O₃ adheres to the film formation surface of the substrate (that is, the yttrium-based protective film is formed), the stress-relaxation layer (or the stress-relaxation layer and the base layer) is formed on the film formation surface of the substrate.

Accordingly, at least the film formation surface of the substrate is covered, and therefore, water of crystallization of the substrate is less likely to be contained in the formed yttrium-based protective film. and further, the number of hydrogen atoms in the yttrium-based protective film is reduced, which is preferable.

### <Pre-Heating of Substrate>

For the reason that water of crystallization of the substrate is less likely to be contained in the yttrium-based protective film, it is preferable to heat (preheat) the substrate at a high temperature before forming the yttrium-based protective film.

The preheating temperature is preferably 300° C. or higher, more preferably 400° C. or higher, still more preferably 450° C. or higher, and particularly preferably 500° C. or higher.

On the other hand, the preheating temperature is, for example, preferably 800° C. or lower, more preferably 750° C. or lower, and still more preferably 700° C. or lower.

The preheating time is preferably 60 minutes or longer, more preferably 120 minutes or longer, still more preferably 240 minutes or longer, and particularly preferably 480 minutes or longer.

On the other hand, the preheating time is preferably 1200 minutes or shorter, more preferably 1000 minutes or shorter, still more preferably 800 minutes or shorter, and particularly preferably 600 minutes or shorter.

The preheating atmosphere is, for example, an air atmosphere.

### EXAMPLES

Hereinafter, the present invention will be specifically described with reference to Examples. However, the present invention is not limited to Examples described below.

Hereinafter, Examples 1 to 49, 53 to 58, and 61 to 82 are Inventive Examples, and Examples 50 to 52 and 59 and 60 are Comparative Examples.

### Example 1

A member including an yttrium-based protective film was produced under the conditions shown in the following Tables 1 to 8 using the apparatus described based on FIG. 5.

As the substrate, a circular substrate (thickness: 10 mm) made of quartz and having a film formation surface with a diameter (maximum length) of a value shown in Tables 1 to 8 below was used.

The substrate was preheated in an air atmosphere while being held by a holder in a chamber. The preheating temperature was 550° C., and the preheating time was 600 minutes.

Next, under the production conditions shown in the following Tables 1 to 8, a base layer, a stress-relaxation layer, and an yttrium-based protective film shown in the following Tables 1 to 8 were formed in this order on a film formation surface of a substrate.

As the production conditions not shown in the following Tables 1 to 8, oxygen (O) ions were emitted from the ion gun, the distance between the ion gun and the substrate was 1100 mm, and the ion beam current value was 2000 mA.

### Examples 2 to 82

In Examples 2 to 82, one or two or more conditions were changed from those in Example 1. Except for this, a base layer, a stress-relaxation layer, and an yttrium-based protective film were formed in this order in the same manner as in Example 1.

When the base layer and/or the stress-relaxation layer were/was not formed, “-” was shown in the corresponding column in the following Tables 1 to 8.

The outlines are as follows. The changes from Example 1 will be mainly outlined.

In Examples 2 to 4, the temperature of the substrate during the formation of the yttrium-based protective film was changed.

In Example 5, the material of the substrate was changed to aluminum oxide (Al₂O₃).

In Example 6, no base layer was formed.

In Examples 7 to 9, the thickness of the yttrium-based protective film was changed.

In Examples 10 to 16, the composition of the stress-relaxation layer was changed.

In Examples 17 to 20, the number of base layers was changed.

In Examples 21 to 27, the composition and/or the number of stress-relaxation layers were/was changed.

In Examples 28 to 31, the thickness of the stress-relaxation layer was changed.

In Examples 32 to 38, the Ra of the film formation surface was mainly changed.

In Example 39, the material of the substrate was changed to glass (commercially available soda lime glass).

In Example 40, the material of the substrate was changed to aluminum (Al).

In Example 41, one surface side of the substrate made of an aluminum single crystal was subjected to an alumite treatment and then to a polishing treatment to form a base layer made of Al₂O₃. This base layer is described as “alumite” in the following Tables 1 to 8.

In Example 42, the material of the substrate was changed to aluminum nitride (AlN).

In Example 43, the material of the substrate was changed to cordierite.

In Examples 44 and 45, the area of the film formation surface was changed (increased).

In Examples 46 to 48, an yttrium-based protective film including yttrium oxyfluoride was formed using Y₂O₃ and YF₃ in combination as evaporation sources.

In Example 49, as described below, after an yttrium-based protective film was formed, heating was performed to precipitate crystals.

In Examples 50 to 52, no stress-relaxation layer was formed.

In Examples 53 and 54, the composition of the stress-relaxation layer was changed.

In Example 55, the thickness of the yttrium-based protective film was increased.

In Example 56, the Ra of the film formation surface was increased.

In Example 57, the crystallite size of the yttrium-based protective film was reduced.

In Example 58, the temperature of the substrate during the formation of the yttrium-based protective film was changed.

In Examples 59 and 60, the yttrium-based protective film was formed using the IP method and the CVD method instead of the IAD method.

In Examples 61 to 82, the material of the substrate was changed to aluminum nitride (AlN).

### <Composition>

The compositions of the base layer, the stress-relaxation layer, and the yttrium-based protective film of each example are shown in the following Tables 1 to 8.

Regarding the base layer and the stress-relaxation layer, for example, “30Y₂O₃+70SiO₂” means that the content of Y₂O₃ is 30 mol %, and the content of SiO₂ is 70 mol %.

When the yttrium-based protective film including yttrium oxyfluoride was formed, the composition obtained from the content of each element (Y, 0, F, etc.) is described as the composition in the following Tables 1 to 8.

### <State of Stress-Relaxation Layer>

The obtained member was subjected to the XRD measurement.

When no peak occurred at components other than the component (yttrium oxide or yttrium oxyfluoride) of the yttrium-based protective film, it was determined that the stress-relaxation layer was an amorphous layer, and “amorphous” was shown in the following Table 3. On the other hand, when a peak occurred, it was determined that the stress-relaxation layer contained a crystal, and “crystal” was shown.

In Example 49, after the yttrium-based protective film was formed, heating was performed at 450° C. for 30 minutes to partially precipitate crystals (Y₂Si₇O₇ crystals). Although the content of the crystals was not clear, with respect to the peak intensity of the yttrium-based protective film (Y₂O₃) having a thickness of 1 μm, the peak intensity of the Y₂Si₇O₇ crystals generated in the stress-relaxation layer having substantially the same thickness was 2.85%. From this, it is considered that the amount of generated crystals was small.

### <Physical Properties>

The thickness of the base layer of each example was determined based on the above-described method.

The thickness and the thermal stabilization temperature of the stress-relaxation layer of each example were determined based on the above-described methods.

The number of hydrogen atoms, the Vickers hardness, the porosity, the crystallite size, the degree of orientation (or the peak intensity ratio), the thickness, and the compressive stress of the yttrium-based protective film of each example were determined based on the above-described method.

All the results are shown in the following Tables 1 to 8. Note that the compressive stress is indicated by a negative numerical value.

### <Etching Amount>

The yttrium-based protective film of each example was subjected to ion etching to evaluate plasma resistance thereof.

Specifically, first, a surface of 10 mm×5 mm in the yttrium-based protective film was mirror-finished, and a Kapton tape was attached to a part of the mirror-finished surface (referred to as a “test surface”) to perform masking.

Next, using a CCP type plasma etching apparatus, plasma was generated by discharging in a gas under conditions of a pressure of 10 Pa and an RF power of 600 W, and a test (exposure test) of exposing the test surface to the generated plasma was performed.

More specifically, discharge (generation of plasma) was performed using CF₄ gas (flow rate: 100 sccm) and O₂ gas (flow rate: 100 sccm), and ions of CF₄ were generated in the plasma.

The discharge (generation of plasma) for 15 minutes was repeated five times, and an exposure test for a total of 150 minutes was performed. Thus, the non-masked portion of the test surface was etched.

Thereafter, the etching amount was determined by measuring a difference between the masked portion and the non-masked portion of the test surface by using a stylus surface profiler (Dectak 150, manufactured by ULVAC, Inc.). Results are shown in the following Tables 1 to 8.

As the etching amount (unit: nm) is smaller, plasma resistance can be evaluated to be excellent.

Specifically, when the etching amount was 200 nm or less, the plasma resistance can be evaluated to be excellent.

### <Heat Resistance Temperature>

For the member of each example, the above-described heat resistance test was performed, and the maximum temperature T1 at which no crack occurred in the yttrium-based protective film was determined as the heat resistance temperature (unit: ° C.). Results are shown in the following Tables 1 to 8.

When the heat resistance temperature is 300° C. or higher, the heat resistance can be evaluated to be excellent.

### <Heat Cycle Test>

A test (heat cycle test) in which the heat resistance test was repeated three times at the determined heat resistance temperature was performed on the members of some examples. Thereafter, an end portion (a portion including an end surface) of the yttrium-based protective film and a portion other than the end portion were visually observed to check the presence or absence of cracks.

In the following Tables 1 to 8, “A” is shown when there was no crack, “B” is shown when there was a crack of less than 10 mm at the end portion but there was no crack at a portion other than the end portion, and “C” is shown when there was a crack of 10 mm or more at the end portion and/or when there was a crack at a portion other than the end portion. From the viewpoint of more excellent heat resistance, “A” or “B” is preferable, and “A” is more preferable.

TABLE 1

| | | | Example 1 | Example 2 | Example 3 | Example 4 | Example 5 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 400 | 320 | 270 | 500 | 320 |
| | Y₂O₃ | Evaporation source | 3.42 | 3.42 | 3.42 | 3.42 | 3.42 |
| | YF₃ | film formation rate | 0 | 0 | 0 | 0 | 0 |
| | | [nm/min] | | | | | |
| | Ion beam current density [μA/cm²] | | 80 | 80 | 80 | 80 | 80 |
| Substrate | Material | | Quartz | Quartz | Quartz | Quartz | Al₂O₃ |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length | 200 | 200 | 200 | 200 | 200 |
| | | [mm] | | | | | |
| Base layer | 1 | Composition | SiO₂ | SiO₂ | SiO₂ | SiO₂ | — |
| | | Thickness [μm] | 0.5 | 0.5 | 0.5 | 0.5 | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 30Y₂O₃ + | 30Y₂O₃ + | 30Y₂O₃ + | 30Y₂O₃ + | 20Y₂O₃ + |
| relaxation | | | 70SiO₂ | 70SiO₂ | 70SiO₂ | 70SiO₂ | 80Al₂O₃ |
| layer | | Thickness [μm] | 1.1 | 1.1 | 1.1 | 1.1 | 1.1 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 500 | 500 | 400 | 500 | 500 |
| Yttrium- | Composition | Y₂O₃ | Y₂O₃ | Y₂O₃ | Y₂O₃ | Y₂O₃ |
| based | Number of hydrogen atoms | 1.8 | 1.8 | 1.9 | 1.8 | 1.8 |
| protective | [×10²¹ atoms/cm³] | | | | | |
| film | Vickers hardness [HV] | 1336 | 1323 | 1309 | 1328 | 1398 |
| | Porosity [volume %] | 0.02 | 0 | 0.01 | 0.05 | 0.02 |
| | Crystallite size [nm] | 11.2 | 9.5 | 7.9 | 15.6 | 9.7 |
| | Degree of orientation [%] | 92.7 | 92.5 | 93.2 | 92.7 | 92.6 |
| | Peak intensity ratio [%] | — | — | — | — | — |
| | Thickness [μm] | 1.0 | 1.0 | 1.0 | 1.0 | 1.0 |
| | Compressive stress [MPa] | −1266 | −1247 | −1233 | −1266 | −1229 |
| | Etching amount [nm] | 72 | 73 | 70 | 75 | 71 |
| | Heat resistance temperature [° C.] | 600 | 500 | 400 | 600 | 600 |

| | | | Example 6 | Example 7 | Example 8 | Example 9 | Example 10 |
|---|---|---|---|---|---|---|---|
| Production | Internal pressure of chamber | | 1 × 10⁻² | 1 × 10⁻² | 1 × 10⁻² | 1 × 10⁻² | 1 × 10⁻² |
| conditions | [Pa] | | | | | | |
| | Temperature [° C.] of | | 320 | 400 | 400 | 400 | 400 |
| | substrate | | | | | | |
| | Y₂O₃ | Evaporation | 3.42 | 3.42 | 3.42 | 3.42 | 3.42 |
| | YF₃ | source film | 0 | 0 | 0 | 0 | 0 |
| | | formation rate | | | | | |
| | | [nm/min] | | | | | |
| | Ion beam current density | | 80 | 80 | 80 | 80 | 80 |
| | [μA/cm²] | | | | | | |
| Substrate | Material | | Quartz | Quartz | Quartz | Quartz | Quartz |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length | 200 | 200 | 200 | 200 | 200 |
| | | [mm] | | | | | |
| Base layer | 1 | Composition | — | SiO₂ | SiO₂ | SiO₂ | SiO₂ |
| | | Thickness [μm] | — | 0.5 | 0.5 | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 30Y₂O₃ + | 30Y₂O₃ + | 30Y₂O₃ + | 30Y₂O₃ + | 22Y₂O₃ + |
| relaxation | | | 70SiO₂ | 70SiO₂ | 70SiO₂ | 70SiO₂ | 19Al₂O₃ + |
| layer | | | | | | | 59SiO₂ |
| | | Thickness [μm] | 1.1 | 1.1 | 1.1 | 1.1 | 1.1 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability | 500 | 500 | 500 | 400 | 500 |
| | temperature [° C.] | | | | | |
| Yttrium- | Composition | Y₂O₃ | Y₂O₃ | Y₂O₃ | Y₂O₃ | Y₂O₃ |
| based | Number of hydrogen atoms | 2.0 | 1.7 | 1.8 | 1.6 | 1.8 |
| protective | [×10²¹ atoms/cm³] | | | | | |
| film | Vickers hardness [HV] | 1319 | 1436 | 1423 | 1441 | 1336 |
| | Porosity [volume %] | 0.08 | 0.02 | 0.03 | 0.05 | 0 |
| | Crystallite size [nm] | 9.8 | 11.4 | 11.5 | 11.3 | 11.1 |
| | Degree of orientation [%] | 91.7 | 92.8 | 92.6 | 93.0 | 93 |
| | Peak intensity ratio [%] | — | — | — | — | — |
| | Thickness [μm] | 1.0 | 5.0 | 10.0 | 16.5 | 1.0 |
| | Compressive stress [MPa] | −1187 | −1268 | −1240 | 1237 | −1269 |
| | Etching amount [nm] | 75 | 72 | 72 | 74 | 76 |
| | Heat resistance temperature | 500 | 600 | 500 | 400 | 800 |
| | [° C.] | | | | | |

TABLE 2

| | | | Example 11 | Example 12 | Example 13 | Example 14 | Example 15 |
|---|---|---|---|---|---|---|---|
| Production | Internal pressure of | | 1 × 10⁻² | 1 × 10⁻² | 1 × 10⁻² | 1 × 10⁻² | 1 × 10⁻² |
| conditions | chamber [Pa] | | | | | | |
| | Temperature [° C.] of | | 320 | 270 | 400 | 320 | 320 |
| | substrate | | | | | | |
| | Y₂O₃ | Evaporation | 3.42 | 3.42 | 3.42 | 3.42 | 3.42 |
| | YF₃ | source film | 0 | 0 | 0 | 0 | 0 |
| | | formation rate | | | | | |
| | | [nm/min] | | | | | |
| | Ion beam current density | | 80 | 80 | 80 | 80 | 80 |
| | [μA/cm²] | | | | | | |
| Substrate | Material | | Quartz | Quartz | Quartz | Quartz | Quartz |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum | 200 | 200 | 200 | 200 | 200 |
| | | length [mm] | | | | | |
| Base layer | 1 | Composition | SiO₂ | SiO₂ | SiO₂ | SiO₂ | SiO₂ |
| | | Thickness | 0.5 | 0.5 | 0.5 | 0.5 | 0.5 |
| | | [μm] | | | | | |
| | 2 | Composition | — | — | — | — | — |
| | | Thickness | — | — | — | — | — |
| | | [μm] | | | | | |
| | 3 | Composition | — | — | — | — | — |
| | | Thickness | — | — | — | — | — |
| | | [μm] | | | | | |
| Stress- | 1 | Composition | 22Y₂O₃ + | 22Y₂O₃ + | 22Y₂O₃ + | 13Y₂O₃ + | 18Y₂O₃ + |
| relaxation | | | 19Al₂O₃ + | 19Al₂O₃ + | 19Al₂O₃ + | 19Al₂O₃ + | 19Al₂O₃ + |
| layer | | | 59SiO₂ | 59SiO₂ | 59SiO₂ | 68SiO₂ | 63SiO₂ |
| | | Thickness | 1.1 | 1.1 | 1.1 | 1.1 | 1.1 |
| | | [μm] | | | | | |
| | 2 | Composition | — | — | — | — | — |
| | | Thickness | — | — | — | — | — |
| | | [μm] | | | | | |

| | | | | | | |
|---|---|---|---|---|---|---|
| | State | Amorphous | Amorphous | Amorphous | Amorphous | Amorphous |
| | Thermal stability | 500 | 500 | 500 | 500 | 500 |
| | temperature [° C.] | | | | | |
| Yttrium- | Composition | Y₂O₃ | Y₂O₃ | Y₂O₃ | Y₂O₃ | Y₂O₃ |
| based | Number of hydrogen | 1.8 | 1.9 | 1.8 | 2.0 | 1.8 |
| protective | atoms [×10²¹ atoms/cm³] | | | | | |
| film | Vickers hardness [HV] | 1323 | 1309 | 1465 | 1376 | 1422 |
| | Porosity [volume %] | 0 | 0.01 | 0 | 0.03 | 0.05 |
| | Crystallite size [nm] | 9.9 | 7.7 | 11 | 9.8 | 9.2 |
| | Degree of orientation [%] | 92.7 | 92.5 | 93.5 | 90.5 | 92.2 |
| | Peak intensity ratio [%] | — | — | — | — | — |
| | Thickness [μm] | 1.0 | 1.0 | 5.0 | 1.0 | 1.0 |
| | Compressive stress [MPa] | −1249 | −1236 | −1259 | −1223 | −1241 |
| | Etching amount [nm] | 77 | 69 | 70 | 77 | 77 |
| | Heat resistance | 800 | 700 | 800 | 800 | 800 |
| | temperature [° C.] | | | | | |

| | | | Example 16 | Example 17 | Example 18 | Example 19 | Example 20 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Quartz | Quartz | Quartz | Quartz | Quartz |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Base layer | 1 | Composition | SiO₂ | SiO₂ | SiO₂ | SiO₂ | SiO₂ |
| | | Thickness [μm] | 0.5 | 0.5 | 0.5 | 0.5 | 0.5 |
| | 2 | Composition | — | 20Al₂O₃ + | 20Al₂O₃ + | ZrO₂ | MgO |
| | | | | 80SiO₂ | 80SiO₂ | | |
| | | Thickness [μm] | — | 1 | 1 | 1 | 1 |
| | 3 | Composition | — | — | Al₂O₃ | Al₂O₃ | Al₂O₃ |
| | | Thickness [μm] | — | — | 1 | 1 | 1 |
| Stress- | 1 | Composition | 25Y₂O₃ + | 30Y₂O₃ + | 30Y₂O₃ + | 30Y₂O₃ + | 30Y₂O₃ + |
| relaxation | | | 25Al₂O₃ + | 70SiO₂ | 70SiO₂ | 70SiO₂ | 70SiO₂ |
| layer | | | 50SiO₂ | | | | |
| | | Thickness [μm] | 1.1 | 1.1 | 1.1 | 1.1 | 1.1 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 500 | 500 | 500 | 500 | 500 |
| Yttrium- | Composition | Y₂O₃ | Y₂O₃ | Y₂O₃ | Y₂O₃ | Y₂O₃ |
| based | Number of hydrogen atoms | 2.1 | 1.8 | 1.8 | 1.9 | 1.8 |
| protective | [×10²¹ atoms/cm³] | | | | | |
| film | Vickers hardness [HV] | 1383 | 1423 | 1422 | 1411 | 1416 |
| | Porosity [volume %] | 0.07 | 0.04 | 0.06 | 0.05 | 0.07 |
| | Crystallite size [nm] | 9.5 | 8.3 | 8.2 | 8.8 | 8.4 |
| | Degree of orientation [%] | 93.0 | 91.6 | 91.7 | 91.9 | 90.9 |
| | Peak intensity ratio [%] | — | — | — | — | — |
| | Thickness [μm] | 1.0 | 3.0 | 3.0 | 3.0 | 3.0 |
| | Compressive stress [MPa] | −1235 | −1240 | −1235 | −1234 | −1231 |
| | Etching amount [nm] | 77 | 73 | 75 | 76 | 75 |
| | Heat resistance temperature [° C.] | 800 | 500 | 500 | 500 | 500 |

TABLE 3

| | | | Example 21 | Example 22 | Example 23 | Example 24 | Example 25 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Quartz | Quartz | Quartz | Quartz | Quartz |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Base layer | 1 | Composition | SiO₂ | SiO₂ | SiO₂ | SiO₂ | SiO₂ |
| | | Thickness [μm] | 0.5 | 0.5 | 0.5 | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 60Al₂O₃ + | 57SiO₂ + | 57SiO₂ + | 10Y₂O₃ + | 80Y₂O₃ + |
| relaxation | | | 40MgO | 13MgO + | 11MgO + | 90SiO₂ | 20SiO₂ |
| layer | | | | 30CaO | 27CaO + 5SrO | | |
| | | Thickness [μm] | 1.1 | 0.5 | 0.5 | 1.1 | 1.1 |
| | 2 | Composition | — | 54SiO₂ + | 54SiO₂ + | — | — |
| | | | | 5Al₂O₃ + | 11MgO + | | |
| | | | | 12MgO + | 27CaO + | | |
| | | | | 29CaO | 5SrO + 3B₂O₃ | | |
| | | Thickness [μm] | — | 0.5 | 0.5 | — | — |

| | | | | | | |
|---|---|---|---|---|---|---|
| | State | Amorphous | Amorphous | Amorphous | Amorphous | Amorphous |
| | Thermal stability temperature [° C.] | 500 | 500 | 500 | 400 | 500 |
| Yttrium- | Composition | Y₂O₃ | Y₂O₃ | Y₂O₃ | Y₂O₃ | Y₂O₃ |
| based | Number of hydrogen atoms | 1.9 | 2.1 | 2.0 | 1.8 | 1.8 |
| protective | [×10²¹ atoms/cm³] | | | | | |
| film | Vickers hardness [HV] | 13.56 | 1345 | 1378 | 1323 | 1323 |
| | Porosity [volume %] | 0.04 | 0.05 | 0.02 | 0 | 0 |
| | Crystallite size [nm] | 9.6 | 9.7 | 9.4 | 9.5 | 9.5 |
| | Degree of orientation [%] | 92.4 | 93.3 | 93.5 | 92.5 | 92.5 |
| | Peak intensity ratio [%] | — | — | — | — | — |
| | Thickness [μm] | 1.0 | 1.0 | 1.0 | 1.0 | 1.0 |
| | Compressive stress [MPa] | −1217 | −1234 | −1241 | −1247 | −1238 |
| | Etching amount [nm] | 73 | 72 | 73 | 71 | 68 |
| | Heat resistance temperature [° C.] | 500 | 600 | 800 | 400 | 500 |

| | | | Example 26 | Example 27 | Example 28 | Example 29 | Example 30 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Quartz | Quartz | Quartz | Quartz | Quartz |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Base layer | 1 | Composition | SiO₂ | SiO₂ | SiO₂ | SiO₂ | SiO₂ |
| | | Thickness [μm] | 0.5 | 0.5 | 0.5 | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 50Y₂O₃ + | 80Y₂O₃ + | 30Y₂O₃ + | 30Y₂O₃ + | 30Y₂O₃ + |
| relaxation | | | 50SiO₂ | 20SiO₂ | 70SiO₂ | 70SiO₂ | 70SiO₂ |
| layer | | Thickness [μm] | 1.1 | 1.1 | 0.1 | 0.5 | 2.9 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 500 | 400 | 500 | 500 | 500 |
| Yttrium- | Composition | Y₂O₃ | Y₂O₃ | Y₂O₃ | Y₂O₃ | Y₂O₃ |
| based | Number of hydrogen atoms | 1.8 | 1.9 | 1.8 | 1.9 | 1.8 |
| protective | [×10²¹ atoms/cm³] | | | | | |
| film | Vickers hardness [HV] | 1323 | 1323 | 1323 | 1323 | 1323 |
| | Porosity [volume %] | 0 | 0 | 0 | 0 | 0 |
| | Crystallite size [nm] | 9.5 | 9.5 | 9.5 | 9.5 | 9.5 |
| | Degree of orientation [%] | 92.5 | 92.5 | 92.5 | 92.5 | 92.5 |
| | Peak intensity ratio [%] | — | — | — | — | — |
| | Thickness [μm] | 1.0 | 1.0 | 1.0 | 1.0 | 1.0 |
| | Compressive stress [MPa] | −1229 | −1278 | −1289 | −1262 | −1259 |
| | Etching amount [nm] | 72 | 73 | 79 | 80 | 85 |
| | Heat resistance temperature [° C.] | 500 | 400 | 400 | 400 | 500 |

TABLE 4

| | | | Example 31 | Example 32 | Example 33 | Example 34 | Example 35 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Quartz | Quartz | Quartz | Quartz | Quartz |
| | Film formation | Ra [μm] | 0.02 | 0.05 | 0.11 | 0.32 | 0.82 |
| | surface | Area [cm²] | 314.2 | 314.2 | 314.2 | 314.2 | 314.2 |
| | | Maximum length [mm] | 200 | 200 | 200 | 200 | 200 |
| Base layer | 1 | Composition | SiO₂ | SiO₂ | SiO₂ | SiO₂ | SiO₂ |
| | | Thickness [μm] | 0.5 | 0.5 | 0.5 | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 30Y₂O₃ + | 30Y₂O₃ + | 30Y₂O₃ + | 30Y₂O₃ + | 30Y₂O₃ + |
| relaxation | | | 70SiO₂ | 70SiO₂ | 70SiO₂ | 70SiO₂ | 70SiO₂ |
| layer | | Thickness [μm] | 7.0 | 1.1 | 1.1 | 1.1 | 1.1 |
| | 2 | Composition | — | — | — | — | — |
| | | Thickness [μm] | — | — | — | — | — |
| | State | | Amorphous | Amorphous | Amorphous | Amorphous | Amorphous |
| | Thermal stability temperature [° C.] | | 500 | 500 | 500 | 500 | 500 |
| Yttrium- | Composition | | Y₂O₃ | Y₂O₃ | Y₂O₃ | Y₂O₃ | Y₂O₃ |
| based | Number of hydrogen atoms | | 1.8 | 1.8 | 1.9 | 2.0 | 2.2 |
| protective | [×10²¹ atoms/cm³] | | | | | | |
| film | Vickers hardness [HV] | | 1323 | 1345 | 1322 | 1275 | 1206 |
| | Porosity [volume %] | | 0 | 0.01 | 0.09 | 0.32 | 0.46 |
| | Crystallite size [nm] | | 9.5 | 9.8 | 9.5 | 9.6 | 9.8 |
| | Degree of orientation [%] | | 92.5 | 91.9 | 90.7 | 89.2 | 80.6 |
| | Peak intensity ratio [%] | | — | — | — | — | — |
| | Thickness [μm] | | 1.0 | 1.0 | 1.0 | 1.0 | 1.0 |
| | Compressive stress [MPa] | | −1247 | −1222 | 1189 | −1120 | −1067 |
| | Etching amount [nm] | | 86 | 72 | 75 | 82 | 101 |
| | Heat resistance temperature [° C.] | | 400 | 600 | 600 | 600 | 500 |
| | | | Example 36 | Example 37 | Example 38 | Example 39 | Example 40 |
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Al₂O₃ | Al₂O₃ | Al₂O₃ | Glass | Al |
| | Film formation | Ra [μm] | 0.44 | 2.77 | 4.03 | 0.02 | 0.02 |
| | surface | Area [cm²] | 314.2 | 314.2 | 314.2 | 314.2 | 314.2 |
| | | Maximum length [mm] | 200 | 200 | 200 | 200 | 200 |
| Base layer | 1 | Composition | — | — | — | SiO₂ | Al₂O₃ |
| | | Thickness [μm] | — | — | — | 0.5 | 1 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 20Y₂O₃ + | 20Y₂O₃ + | 20Y₂O₃ + | 30Y₂O₃ + | 20Y₂O₃ + |
| relaxation | | | 80Al₂O₃ | 80Al₂O₃ | 80Al₂O₃ | 70SiO₂ | 80Al₂O₃ |
| layer | | Thickness [μm] | 1.1 | 1.1 | 1.1 | 1.1 | 1.1 |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 500 | 500 | 500 | 500 | 500 |
| Yttrium- | Composition | Y₂O₃ | Y₂O₃ | Y₂O₃ | Y₂O₃ | Y₂O₃ |
| based | Number of hydrogen atoms | 1.9 | 2.2 | 2.4 | 1.5 | 1.4 |
| protective | [×10²¹ atoms/cm³] | | | | | |
| film | Vickers hardness [HV] | 1387 | 1288 | 1079 | 1027 | 976 |
| | Porosity [volume %] | 0.38 | 0.73 | 1.03 | 0.01 | 0.13 |
| | Crystallite size [nm] | 9.7 | 9.7 | 9.6 | 9.4 | 9.6 |
| | Degree of orientation [%] | 88.4 | 69.6 | 58.3 | 94.6 | 90.5 |
| | Peak intensity ratio [%] | — | — | — | — | — |
| | Thickness [μm] | 1.0 | 1.0 | 1.0 | 1.0 | 1.0 |
| | Compressive stress [MPa] | −1054 | −812 | −723 | −834 | −1037 |
| | Etching amount [nm] | 85 | 128 | 143 | 83 | 99 |
| | Heat resistance temperature [° C.] | 600 | 500 | 400 | 600 | 500 |

TABLE 5

| | | | Example 41 | Example 42 | Example 43 | Example 44 | Example 45 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature[° C.] of substrate | | 320 | 320 | 320 | 320 | 320 |
| | Y₂O₃ | Evaporation source film | 3.42 | 3.42 | 3.42 | 3.42 | 3.42 |
| | YF₃ | formation rate [nm/min] | 0 | 0 | 0 | 0 | 0 |
| | Ion beam current density [μA/cm²] | | 80 | 80 | 80 | 80 | 80 |
| Substrate | Material | | Al | AlN | Cordierite | Quartz | Al₂O₃ |
| | Film | Ra [μm] | 0.02 | 0.02 | 0.02 | 0.02 | 0.02 |
| | formation | Area [cm²] | 314.2 | 314.2 | 314.2 | 9503.0 | 9503.0 |
| | surface | Maximum length [mm] | 200 | 200 | 200 | 1100 | 1100 |
| Base layer | 1 | Composition | Alumite | Al₂O₃ | Al₂O₃ | SiO₂ | — |
| | | Thickness [μm] | 1 | 1 | 1 | 0.5 | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 20Y₂O₃ + | 30Y₂O₃ + | 30Y₂O₃ + | 30Y₂O₃ + | 20Y₂O₃ + |
| relaxation | | | 80Al₂O₃ | 70SiO₂ | 70SiO₂ | 70SiO₂ | 80Al₂O₃ |
| layer | | Thickness [μm] | 1.1 | 1.1 | 1.1 | 1.1 | 1.1 |
| | 2 | Composition | — | — | — | — | — |
| | | Thickness [μm] | — | — | — | — | — |
| | State | | Amorphous | Amorphous | Amorphous | Amorphous | Amorphous |
| | Thermal stability temperature [° C.] | | 500 | 500 | 500 | 500 | 500 |
| Yttrium- | Composition | | Y₂O₃ | Y₂O₃ | Y₂O₃ | Y₂O₃ | Y₂O₃ |
| based | Number of hydrogen atoms | | 1.8 | 2.1 | 1.9 | 1.2 | 1.4 |
| protective | [×10²¹ atoms/cm³] | | | | | | |
| film | Vickers hardness [HV] | | 1183 | 1261 | 1318 | 1320 | 1378 |
| | Porosity [volume %] | | 0.28 | 0.32 | 0.05 | 0.06 | 0.02 |
| | Crystallite size [nm] | | 9.5 | 9.8 | 9.8 | 9.8 | 9.7 |
| | Degree of orientation [%] | | 91.8 | 90.9 | 92.2 | 90.3 | 91.2 |
| | Peak intensity ratio [%] | | — | — | — | — | — |
| | Thickness [μm] | | 1.0 | 1.0 | 1.0 | 1.0 | 1.0 |
| | Compressive stress [MPa] | | −1098 | −1103 | −1225 | −1227 | −1242 |
| | Etching amount [nm] | | 72 | 70 | 74 | 77 | 80 |
| | Heat resistance temperature [° C.] | | 500 | 600 | 500 | 500 | 600 |
| | | | Example 46 | Example 47 | Example 48 | Example 49 | Example 50 |
| Production | Internal pressure of chamber [Pa] | | 1 × 10⁻² | 1 × 10⁻² | 1 × 10⁻² | 1 × 10⁻² | 1 × 10⁻² |
| conditions | Temperature[° C.] of substrate | | 320 | 320 | 320 | 320 | 400 |
| | Y₂O₃ | Evaporation source film | 1.92 | 6.78 | 3.42 | 3.42 | 3.42 |
| | YF₃ | formation rate [nm/min] | 13.36 | 8.76 | 11.88 | 0 | 0 |
| | Ion beam current density [μA/cm²] | | 96 | 96 | 96 | 80 | 80 |
| Substrate | Material | | Quartz | Quartz | Quartz | Quartz | Quartz |
| | Film | Ra [μm] | 0.03 | 0.03 | 0.03 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Base layer | 1 | Composition | SiO₂ | SiO₂ | SiO₂ | SiO₂ | — |
| | | Thickness [μm] | 0.5 | 0.5 | 0.5 | 0.5 | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 30Y₂O₃ + | 30Y₂O₃ + | 30Y₂O₃ + | 80Y₂O₃ + | — |
| relaxation | | | 70SiO₂ | 70SiO₂ | 70SiO₂ | 20SiO₂ | |
| layer | | Thickness [μm] | 1.1 | 1.1 | 1.1 | 1.1 | — |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Crystal | — |
| | Thermal stability temperature [° C.] | 500 | 500 | 500 | 400 | — |
| Yttrium- | Composition | Y₅O_{4.3}F_{9.6} | Y₅O_{4.3}F_{8.7} | Y₅O_{4.2}F_{9.1} | Y₂O₃ | Y₂O₃ |
| based | Number of hydrogen atoms | 1.7 | 1.8 | 2.0 | 1.9 | 1.8 |
| protective | [×10²¹ atoms/cm³] | | | | | |
| film | Vickers hardness [HV] | 998 | 1068 | 1103 | 1201 | 1432 |
| | Porosity [volume %] | 0.16 | 0.10 | 0.05 | 0.13 | 0.03 |
| | Crystallite size [nm] | 16.7 | 8.9 | 13.6 | 14.1 | 11.4 |
| | Degree of orientation [%] | — | — | — | 91.2 | 92.3 |
| | Peak intensity ratio [%] | 95.2 | 99.8 | 100 | — | — |
| | Thickness [μm] | 1.0 | 1.0 | 1.0 | 1.0 | 10.0 |
| | Compressive stress [MPa] | −798 | −912 | −831 | −1084 | −1235 |
| | Etching amount [nm] | 97 | 78 | 75 | 84 | 73 |
| | Heat resistance temperature [° C.] | 400 | 500 | 500 | 400 | 250 |

TABLE 6

| | | | Example 51 | Example 52 | Example 53 | Example 54 | Example 55 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 400 | 270 | 400 | 400 | 320 |
| | Y₂O₃ | Evaporation source film | 3.42 | 1.92 | 3.42 | 3.42 | 3.42 |
| | YF₃ | formation rate [nm/min] | 0 | 13.36 | 0 | 0 | 0 |
| | Ion beam current density [μA/cm²] | | 80 | 96 | 80 | 80 | 80 |
| Substrate | Material | | Quartz | Quartz | Quartz | Quartz | Quartz |
| | Film | Ra [μm] | 0.02 | 0.03 | 0.02 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Base layer | 1 | Composition | — | — | SiO₂ | SiO₂ | SiO₂ |
| | | Thickness [μm] | — | — | 0.5 | 0.5 | 0.5 |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | — | — | 5Y₂O₃ + | 90Y₂O₃ + | 30Y₂O₃ + |
| relaxation | | | | | 95SiO₂ | 10SiO₂ | 70SiO₂ |
| layer | | Thickness [μm] | — | — | 1.1 | 1.1 | 1.1 |
| | 2 | Composition | — | — | — | — | — |
| | | Thickness [μm] | — | — | — | — | — |

| | | | | | | |
|---|---|---|---|---|---|---|
| | State | — | — | Amorphous | Amorphous | Amorphous |
| | Thermal stability temperature [° C.] | — | — | Not measured | Not measured | 500 |
| Yttrium- | Composition | Y₂O₃ | Y₅O_{4.3}F_{9.6} | Y₂O₃ | Y₂O₃ | Y₂O₃ |
| based | Number of hydrogen atoms | 2.0 | 1.7 | 2.2 | 1.9 | 2.0 |
| protective | [×10²¹ atoms/cm³] | | | | | |
| film | Vickers hardness [HV] | 1430 | 1021 | 1345 | 1372 | 1332 |
| | Porosity [volume %] | 0.03 | 0.12 | 0.06 | 0.02 | 0.07 |
| | Crystallite size [nm] | 11.7 | 16.6 | 9.4 | 9.8 | 9.8 |
| | Degree of orientation [%] | 92.5 | — | 94.1 | 92.2 | 93.0 |
| | Peak intensity ratio [%] | — | 95.1 | — | — | — |
| | Thickness [μm] | 10.0 | 1.0 | 1.0 | 1.0 | 114.2 |
| | Compressive stress [MPa] | −1229 | −1187 | −1233 | −1239 | −1247 |
| | Etching amount [nm] | 72 | 97 | 81 | 82 | 73 |
| | Heat resistance temperature [° C.] | 250 | 250 | 300 | 300 | 300 |

| | | | Example 56 | Example 57 | Example 58 | Example 59 | Example 60 |
|---|---|---|---|---|---|---|---|
| Production | Internal pressure of chamber [Pa] | | 1 × 10⁻² | 1 × 10⁻² | 1 × 10⁻² | — | — |
| conditions | Temperature [° C.] of substrate | | 320 | 320 | 200 | — | — |
| | Y₂O₃ | Evaporation source film | 3.42 | 3.31 | 3.42 | — | — |
| | YF₃ | formation rate [nm/min] | 0 | 0 | 0 | — | — |
| | Ion beam current density [μA/cm²] | | 80 | 80 | 80 | — | — |
| Substrate | Material | | Al₂O₃ | Quartz | Quartz | Quartz | Quartz |
| | Film formation | Ra [μm] | 6.74 | 0.02 | 0.02 | 0.02 | 0.02 |
| | surface | Area [cm²] | 314.2 | 314.2 | 314.2 | 314.2 | 314.2 |
| | | Maximum length [mm] | 200 | 200 | 200 | 200 | 200 |
| Base layer | 1 | Composition | — | SiO₂ | SiO₂ | SiO₂ | — |
| | | Thickness [μm] | — | 0.5 | 0.5 | 0.5 | — |
| | 2 | Composition | — | — | — | — | — |
| | | Thickness [μm] | — | — | — | — | — |
| | 3 | Composition | — | — | — | — | — |
| | | Thickness [μm] | — | — | — | — | — |
| Stress- | 1 | Composition | 20Y₂O₃ + | 30Y₂O₃ + | 30Y₂O₃ + | 30Y₂O₃ + | — |
| relaxation | | | 80Al₂O₃ | 70SiO₂ | 70SiO₂ | 70SiO₂ | |
| layer | | Thickness [μm] | 1.1 | 1.1 | 1.1 | 1.1 | — |
| | 2 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | — |
| | Thermal stability temperature [° C.] | 500 | 500 | 500 | 500 | — |
| Yttrium- | Composition | Y₂O₃ | Y₂O₃ | Y₂O₃ | Y₂O₃ | Y₂O₃ |
| based | Number of hydrogen atoms | 2.4 | 2.1 | 2.4 | 5.1 | 6.4 |
| protective | [×10²¹ atoms/cm³] | | | | | |
| film | Vickers hardness [HV] | 832 | 1310 | 1172 | 775 | 583 |
| | Porosity [volume %] | 2.12 | 0 | 0 | 0.05 | 0.03 |
| | Crystallite size [nm] | 8.4 | 5.6 | 5.5 | 7.1 | 7.9 |
| | Degree of orientation [%] | 47.8 | 92.2 | 93.5 | 67.5 | 75.2 |
| | Peak intensity ratio [%] | — | — | — | — | — |
| | Thickness [μm] | 1.0 | 1.0 | 1.0 | 1.0 | 1.0 |
| | Compressive stress [MPa] | −589 | −1324 | −1302 | −1537 | −573 |
| | Etching amount [nm] | 190 | 92 | 88 | 205 | 219 |
| | Heat resistance temperature [° C.] | 300 | 300 | 300 | 200 | 250 |

TABLE 7

| | | | Example 61 | Example 62 | Example 63 | Example 64 | Example 65 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 320 | 350 | 350 | 350 | 350 |
| | Y₂O₃ | Evaporation source | 1.9 | 3.42 | 3.42 | 3.42 | 3.42 |
| | YF₃ | film formation rate | 0 | 0 | 0 | 0 | 0 |
| | | [nm/min] | | | | | |
| | Ion beam current density [μA/cm²] | | 85 | 80 | 80 | 80 | 70 |
| Substrate | Material | | AlN | AlN | AlN | AlN | AlN |
| | Film | Ra [μm] | 0.02 | 0.02 | 0.02 | 0.02 | 0.02 |
| | formation | Area [cm²] | 314.2 | 314.2 | 314.2 | 314.2 | 314.2 |
| | surface | Maximum length [mm] | 200 | 200 | 200 | 200 | 200 |
| Stress- | 1 | Composition | Al₂O₃ | Al₂O₃ | Al₂O₃ | Al₂O₃ | Al₂O₃ |
| relaxation | | Thickness [μm] | 1 | 1 | 1 | 1 | 1 |
| layer | 2 | Composition | — | — | — | — | — |
| | | Thickness [μm] | — | — | — | — | — |
| | 3 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 600 | 600 | 600 | 600 | 600 |
| Yttrium- | Composition | Y₂O₃ | Y₂O₃ | Y₂O₃ | Y₂O₃ | Y₂O₃ |
| based | Number of hydrogen atoms | 1.9 | 1.9 | 2.2 | 2.3 | 2.0 |
| protective | [×10²¹ atoms/cm³] | | | | | |
| film | Vickers hardness [HV] | 1263 | 1287 | 1098 | 1309 | 922 |
| | Porosity [volume %] | 0.04 | 0.05 | 0 | 0.05 | 0.12 |
| | Crystallite size [nm] | 10.2 | 11.8 | 11.3 | 12.2 | 12.1 |
| | Degree of orientation [%] | 92.1 | 91.8 | 93.2 | 92.0 | 91.9 |
| | Thickness [μm] | 10.5 | 10.2 | 1.2 | 15.1 | 10.6 |
| | Compressive stress [MPa] | −1349 | −1393 | −1089 | −1407 | −989 |
| | Etching amount [nm] | 72 | 78 | 81 | 82 | 132 |
| | Heat resistance temperature [° C.] | 600 | 600 | 600 | 600 | 600 |
| | Heat cycle test | B | A | B | A | B |

| | | | Example 66 | Example 67 | Example 68 | Example 69 | Example 70 | Example 71 |
|---|---|---|---|---|---|---|---|---|
| Production | Internal pressure of chamber | | 1 × 10⁻² | 1 × 10⁻² | 1 × 10⁻² | 1 × 10⁻² | 1 × 10⁻² | 1 × 10⁻² |
| conditions | [Pa] | | | | | | | |
| | Temperature [° C.] of substrate | | 350 | 350 | 350 | 350 | 350 | 350 |
| | Y₂O₃ | Evaporation source | 3.42 | 3.42 | 3.42 | 3.42 | 3.42 | 3.42 |
| | YF₃ | film formation rate | 0 | 0 | 0 | 0 | 0 | 0 |
| | | [nm/min] | | | | | | |
| | Ion beam current density | | 80 | 80 | 80 | 80 | 80 | 80 |
| | [μA/cm²] | | | | | | | |
| Substrate | Material | | AlN | AlN | AlN | AlN | AlN | AlN |
| | Film | Ra [μm] | 0.02 | 0.02 | 0.02 | 0.02 | 0.02 | 0.05 |
| | formation | Area [cm²] | 314.2 | 314.2 | 314.2 | 314.2 | 314.2 | 314.2 |
| | surface | Maximum length | 200 | 200 | 200 | 200 | 200 | 200 |
| | | [mm] | | | | | | |
| Stress- | 1 | Composition | Al₂O₃ | Al₂O₃ | ZrO₂ | MgO | MgO | Al₂O₃ |
| relaxation | | Thickness [μm] | 0.3 | 1.5 | 1 | 1 | 1 | 1 |
| layer | 2 | Composition | — | — | — | — | Al₂O₃ | — |
| | | Thickness [μm] | — | — | — | — | 1 | — |
| | 3 | Composition | — | — | — | — | — | — |
| | | Thickness [μm] | — | — | — | — | — | — |

| | | | | | | | |
|---|---|---|---|---|---|---|---|
| | State | Amorphous | Amorphous | Amorphous | Amorphous | Amorphous | Amorphous |
| | Thermal stability temperature | 600 | 600 | Not | Not | Not | 600 |
| | [° C.] | | | measured | measured | measured | |
| Yttrium- | Composition | Y₂O₃ | Y₂O₃ | Y₂O₃ | Y₂O₃ | Y₂O₃ | Y₂O₃ |
| based | Number of hydrogen atoms | 2.1 | 1.8 | 2.5 | 2.7 | 2.4 | 1.9 |
| protective | [×10²¹ atoms/cm³] | | | | | | |
| film | Vickers hardness [HV] | 1255 | 1284 | 1055 | 1041 | 1201 | 1292 |
| | Porosity [volume %] | 0.08 | 0 | 0.05 | 0.06 | 0.13 | 0.06 |
| | Crystallite size [nm] | 12.0 | 12.1 | 10.5 | 9.9 | 11.4 | 12.4 |
| | Degree of orientation [%] | 90.5 | 92.9 | 90.1 | 89.7 | 90.3 | 90.8 |
| | Thickness [μm] | 10.1 | 10.3 | 10.2 | 10.1 | 10.2 | 10.0 |
| | Compressive stress [MPa] | −1420 | −1263 | −1097 | −1078 | −1185 | −1401 |
| | Etching amount [nm] | 80 | 72 | 81 | 89 | 85 | 77 |
| | Heat resistance temperature | 600 | 600 | 600 | 600 | 600 | 600 |
| | [° C.] | | | | | | |
| | Heat cycle test | B | A | A | B | A | A |

TABLE 8

| | | | Example 72 | Example 73 | Example 74 | Example 75 | Example 76 |
|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² |
| conditions | Temperature [° C.] of substrate | | 350 | 350 | 350 | 300 | 300 |
| | Y₂O₃ | Evaporation source | 3.42 | 3.42 | 3.42 | 2.1 | 2.1 |
| | YF₃ | film formation rate | 0 | 0 | 0 | 0 | 0 |
| | | [nm/min] | | | | | |
| | Ion beam current density [μA/cm²] | | 80 | 80 | 80 | 80 | 80 |
| Substrate | Material | | AlN | AlN | AlN | AlN | AlN |
| | Film formation | Ra [μm] | 0.11 | 0.02 | 0.02 | 0.03 | 0.05 |
| | surface | Area [cm²] | 314.2 | 17670.9 | 3848.3 | 314.2 | 314.2 |
| | | Maximum length | 200 | 1500 | 700 | 200 | 200 |
| | | [mm] | | | | | |
| Stress- | 1 | Composition | Al₂O₃ | Al₂O₃ | Al₂O₃ | Al₂O₃ | Al₂O₃ |
| relaxation | | Thickness [μm] | 1 | 1 | 1 | 1 | 1 |
| layer | 2 | Composition | — | — | — | — | — |
| | | Thickness [μm] | — | — | — | — | — |
| | 3 | Composition | — | — | — | — | — |
| | | Thickness [μm] | — | — | — | — | — |

| | | | | | | |
|---|---|---|---|---|---|---|
| | State | Amorphous | Amorphous | Amorphous | Amorphous | Amorphous |
| | Thermal stability temperature [° C.] | 600 | 600 | 600 | 600 | 600 |
| Yttrium- | Composition | Y₂O₃ | Y₂O₃ | Y₂O₃ | Y₂O₃ | Y₂O₃ |
| based | Number of hydrogen atoms | 1.9 | 1.9 | 2.1 | 2.0 | 2.0 |
| protective | [×10²¹ atoms/cm³] | | | | | |
| film | Vickers hardness [HV] | 1032 | 1180 | 1254 | 1102 | 1094 |
| | Porosity [volume %] | 0.14 | 0 | 0 | 0.05 | 0.11 |
| | Crystallite size [nm] | 12.3 | 12.6 | 12.5 | 12.3 | 12.1 |
| | Degree of orientation [%] | 90.2 | 90.9 | 91.2 | 84.9 | 80.1 |
| | Thickness [μm] | 10.0 | 9.8 | 10.3 | 10.3 | 10.2 |
| | Compressive stress [MPa] | −1084 | −1288 | 1328 | −1081 | −1043 |
| | Etching amount [nm] | 122 | 78 | 82 | 75 | 75 |
| | Heat resistance temperature [° C.] | 600 | 600 | 600 | 500 | 500 |
| | Heat cycle test | B | B | A | C | C |

| | | | Example 77 | Example 78 | Example 79 | Example 80 | Example 81 | Example 82 |
|---|---|---|---|---|---|---|---|---|
| Production | Internal pressure of chamber [Pa] | | 1 × 10⁻² | 1 × 10⁻² | 1 × 10⁻² | 1 × 10⁻² | 1 × 10⁻² | 5 × 10⁻² |
| conditions | Temperature [° C.] of substrate | | 300 | 320 | 350 | 350 | 350 | 350 |
| | Y₂O₃ | Evaporation source | 2.1 | 3.42 | 3.42 | 3.42 | 3.61 | 3.42 |
| | YF₃ | film formation rate | 0 | 0 | 0 | 0 | 0 | 0 |
| | | [nm/min] | | | | | | |
| | Ion beam current density [μA/cm²] | | 80 | 80 | 80 | 80 | 75 | 80 |
| Substrate | Material | | AlN | AlN | AlN | AlN | AlN | AlN |
| | Film | Ra [μm] | 0.1 | 0.02 | 0.02 | 0.22 | 0.02 | 0.02 |
| | formation | Area [cm²] | 314.2 | 314.2 | 314.2 | 314.2 | 314.2 | 314.2 |
| | surface | Maximum length | 200 | 200 | 200 | 200 | 200 | 200 |
| | | [mm] | | | | | | |
| Stress- | 1 | Composition | Al₂O₃ | Al₂O₃ | Al₂O₃ | Al₂O₃ | β-Al₂O₃ | Al₂O₃ |
| relaxation | | Thickness [μm] | 1 | 1 | 0.02 | 1 | 1 | 1 |
| layer | 2 | Composition | — | 30Y₂O₃ + | — | — | — | — |
| | | | | 70SiO₂ | | | | |
| | | Thickness [μm] | — | — | — | — | — | — |
| | 3 | Composition | — | — | — | — | — | — |
| | | Thickness [μm] | — | — | — | — | — | — |

| | | | | | | | |
|---|---|---|---|---|---|---|---|
| | State | Amorphous | Amorphous | Amorphous | Amorphous | Amorphous | Amorphous |
| | Thermal stability temperature [° C.] | 600 | 500 | 600 | 600 | Not | 600 |
| | | | | | | measured | |
| Yttrium- | Composition | Y₂O₃ | Y₂O₃ | Y₂O₃ | Y₂O₃ | Y₂O₃ | Y₂O₃ |
| based | Number of hydrogen atoms | 2.0 | 2.1 | 2.2 | 1.9 | 2.1 | 3.1 |
| protective | [×10²¹ atoms/cm³] | | | | | | |
| film | Vickers hardness [HV] | 1032 | 1109 | 1226 | 1018 | 979 | 1030 |
| | Porosity [volume %] | 0.18 | 0.32 | 0.11 | 0.21 | 0.15 | 0.11 |
| | Crystallite size [nm] | 12.4 | 9.8 | 11.9 | 11.8 | 10.2 | 10.1 |
| | Degree of orientation [%] | 74.8 | 90.9 | 90.7 | 70.3 | 89.7 | 83.4 |
| | Thickness [μm] | 10.3 | 1.0 | 10.2 | 10.2 | 10.1 | 10.6 |
| | Compressive stress [MPa] | −1019 | −1103 | −1367 | −1095 | −1017 | −1003 |
| | Etching amount [nm] | 76 | 79 | 86 | 110 | 121 | 131 |
| | Heat resistance temperature [° C.] | 500 | 600 | 600 | 600 | 500 | 500 |
| | Heat cycle test | C | C | C | C | C | C |

### Conclusion of Evaluation Results

As shown in the above Tables 1 to 8, it was found that Examples 1 to 49, Examples 53 to 58, and Examples 61 to 82 had excellent heat resistance and excellent plasma resistance. In contrast, in Examples 50 to 52 in which the stress-relaxation layer was not included and Examples 59 and 60 in which the Vickers hardness of the yttrium-based protective film was less than 800 HV, at least one of the heat resistance or the plasma resistance was insufficient.

Although the present invention has been described in detail with reference to specific embodiments, it is apparent to those skilled in the art that various changes and modifications can be made without departing from the spirit and scope of the present invention. The present application is based on Japanese Patent Application (No. 2022-181022) filed on Nov. 11, 2022, and Japanese Patent Application (No. 2023-053613) filed on Mar. 29, 2023, and the contents of which are incorporated herein by reference.

### REFERENCE SIGNS LIST

1, 2, 3: base layer
4: yttrium-based protective film
5: substrate
6: member
7: film formation surface
7a: first film formation surface
7b: second film formation surface
8, 9: stress-relaxation layer
11: chamber
12, 13: crucible
14: ion gun
15: heater
16: support shaft
17: holder
18, 19: crystal type film thickness monitor

1. A member comprising:
a substrate;
at least one stress-relaxation layer; and
an yttrium-based protective film, in this order,
wherein the yttrium-based protective film has a Vickers hardness of 800 HV or more.

2. The member according to claim 1, wherein the yttrium-based protective film has a heat resistance temperature of 300° C. or higher.

3. The member according to claim 1, wherein the stress-relaxation layer has a thickness of 0.05 μm to 9.0 μm.

4. The member according to claim 1, wherein the substrate has a surface roughness on a film formation surface of 0.001 μm or more and less than 4.5 μm in terms of an arithmetic average roughness Ra.

5. The member according to claim 1, wherein the stress-relaxation layer comprises at least one oxide selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

6. The member according to claim 5, wherein the stress-relaxation layer comprises at least two oxides selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

7. The member according to claim 5,
wherein the stress-relaxation layer comprises at least one oxide selected from the group consisting of Al₂O₃, SiO₂, and Y₂O₃,
the stress-relaxation layer has a content of Al₂O₃ of 0 mol % to 70 mol %,
the stress-relaxation layer has a content of SiO₂ of 0 mol % to 90 mol %,
the stress-relaxation layer has a content of Y₂O₃ of 0 mol % to 60 mol %, and
the stress-relaxation layer has a content of the oxide excluding Al₂O₃, SiO₂, and Y₂O₃ of 20 mol % or less.

8. The member according to claim 5,
wherein the stress-relaxation layer comprises SiO₂ and Y₂O₃,
the stress-relaxation layer has SiO₂/Y₂O₃, which is a molar ratio of SiO₂ to Y₂O₃, of 90/10 to 20/80, and
the stress-relaxation layer has a content of the oxide excluding SiO₂ and Y₂O₃ of 10 mol % or less.

9. The member according to claim 5,
wherein the stress-relaxation layer comprises Al₂O₃, and
the stress-relaxation layer has a content of Al₂O₃ of 10 mol % to 70 mol %.

10. The member according to claim 1, further comprising:
at least one base layer between the substrate and the stress-relaxation layer,
wherein the base layer comprises at least one oxide selected from the group consisting of Al₂O₃, SiO₂, Y₂O₃, MgO, ZrO₂, La₂O₃, Nd₂O₃, Yb₂O₃, Eu₂O₃, and Gd₂O₃.

11. The member according to claim 10, comprising:
two or more of the base layers,
wherein the oxides in the adjacent base layers are different from each other.

12. The member according to claim 10, wherein the base layer comprises SiO₂, or comprises at least two oxides selected from the group consisting of Al₂O₃, SiO₂, and Y₂O₃.

13. The member according to claim 1, wherein the yttrium-based protective film has a porosity of less than 2.0 volume %.

14. The member according to claim 1, wherein the yttrium-based protective film has a thickness of 0.3 μm or more and 15 μm or less.

15. The member according to claim 1, wherein the yttrium-based protective film has a crystallite size of 6 nm or more and 40 nm or less.

16. The member according to claim 1, wherein the yttrium-based protective film comprises an yttrium oxide.

17. The member according to claim 16, wherein a degree of orientation of a (222) plane of Y₂O₃ in the yttrium-based protective film is 50% or more.

18. The member according to claim 1, wherein the yttrium-based protective film has a peak intensity ratio of Y₅O₄F₇ in an X-ray diffraction pattern of 60% or more.

19. The member according to claim 1, wherein the substrate is formed of at least one selected from the group consisting of carbon, ceramic, and metal.

20. The member according to claim 19, wherein the ceramic is aluminum oxide or quartz.

21. The member according to claim 1,
wherein a maximum length of a film formation surface of the substrate is 30 mm or more,
the substrate comprises, as the film formation surface, a first film formation surface defining the maximum length and a second film formation surface different from the first film formation surface,
an angle formed by the first film formation surface and the second film formation surface is 200 to 120°, and
a proportion of an area of the second film formation surface to a total area of the film formation surfaces is 60% or less.

22. The member according to claim 1, which is used in a plasma etching apparatus or a plasma CVD apparatus.

23. A method for producing the member according to claim 1, the method comprising:
forming the yttrium-based protective film by causing an evaporation source to evaporate and adhere to a surface of the stress-relaxation layer while emitting ions of at least one element selected from the group consisting of oxygen, argon, neon, krypton, and xenon in a vacuum,
wherein Y₂O₃ is used, or Y₂O₃ and YF₃ are used as the evaporation source.

24. The method for producing the member according to claim 23, wherein the substrate has a temperature of 320° C. or higher during the formation of the yttrium-based protective film.

25. The method for producing the member according to claim 23, wherein the at least one stress-relaxation layer is formed on a surface of the substrate before forming the yttrium-based protective film.
